(19) United States
(12) Patent Application Publication
(10) Pub. No.: US 2024/0302743 A1
(43) Pub. Date: Sep. 12, 2024

(54) RESIST COMPOSITION AND METHOD FOR FORMING RESIST PATTERN

(71) Applicant: TOKYO OHKA KOGYO CO., LTD., Kawasaki-shi (JP)

(72) Inventors: Tomoyuki Hirano, Kawasaki-shi (JP); Koji Yonemura, Kawasaki-shi (JP); Yusuke Nakagawa, Kawasaki-shi (JP)

(21) Appl. No.: 18/254,802

(22) PCT Filed: Dec. 21, 2021
(86) PCT No.: PCT/JP2021/047337

§ 371 Date: May 26, 2023

(30) Foreign Application Priority Data
Dec. 21, 2020 (JP) 2020-211619

(51) Int. Cl. G03F 7/039; G03F 7/038

(52) U.S. Cl. CPC G03F 7/039; G03F 7/038

(57) ABSTRACT

A resist composition containing a polymeric compound having a constitutional unit containing a phenolic hydroxyl group, an acid generator, at least one crosslinking agent among a melamine-based crosslinking agent, a urea-based crosslinking agent, an alkylene urea-based crosslinking agent, a glycoluril-based crosslinking agent, and an epoxy-based crosslinking agent, and a polyether compound, a content of which is less than 50 parts by mass with respect to 100 parts by mass of the polymeric compound.

### TECHNICAL FIELD

The present invention relates to a resist composition and a method for forming a resist pattern.

Priority is claimed on Japanese Patent Application No. 2020-211619, filed on Dec. 21, 2020, the content of which is incorporated herein by reference.

### BACKGROUND ART

In recent years, in the production of semiconductor elements and liquid crystal display elements, with advances in lithography techniques, rapid progress in the field of pattern fining has been achieved. Typically, pattern fining techniques involve shortening the wavelength (increasing the energy) of the light source for exposure.

Resist materials have been required to have lithography characteristics such as sensitivity to these light sources for exposure and resolution capable of reproducing a fine-sized pattern.

As a resist material that satisfies these requirements, a chemical amplification-type resist composition that contains a base material component that exhibits changed solubility in a developing solution under action of acid, and an acid generator component that generates acid upon exposure has been conventionally used in the related art.

Resist materials have been required to have lithography characteristics such as sensitivity to these light sources for exposure and resolution capable of reproducing a fine-sized pattern.

As a resist material that satisfies these requirements, a chemical amplification-type resist composition that contains a base material component that exhibits changed solubility in a developing solution under action of acid, and an acid generator component that generates acid upon exposure has been conventionally used in the related art.

For example, in a case where the developing solution is an alkali developing solution (alkali developing process), as a positive-tone chemical amplification-type resist composition, a composition which contains a resin component (a base resin) exhibiting increased solubility in an alkali developing solution under action of acid and an acid generator component has been typically used. In a case where a resist film formed using such a resist composition is selectively exposed at the time of resist pattern formation, in exposed portions, acid is generated from the acid generator component, and the polarity of the base resin increases under the action of the generated acid, thereby making exposed portions of the resist film soluble in the alkali developing solution. Accordingly, a positive-tone pattern in which unexposed portions of the resist film remain as a pattern is formed by performing alkali development.

In addition, a chemical amplification-type resist composition containing a base material component (an alkali-soluble base material component) that is soluble in an alkali developing solution, an acid generator component that generates acid upon exposure, and a crosslinking agent component, has also been used in the related art as a resist material. In such a chemical amplification-type resist composition, for example, in a case where acid is generated from an acid generator component upon exposure, the acid acts to cause crosslinking between the alkali-soluble base material component and the crosslinking agent component, and as a result, solubility in alkali developing solution decreases. Therefore, in the resist pattern formation, in a case where a resist film formed by applying such a chemical amplification-type resist composition onto a support is subjected to the selective exposure, exposed portions of the resist film change to be insoluble in an alkali developing solution, whereas unexposed portions of the resist film remain soluble in the alkali developing solution, and thus, a negative-tone resist pattern is formed by carrying out development with the alkali developing solution.

For example, Patent Document 1 describes a negative-tone chemical amplification-type resist composition containing an alkali-soluble polyhydroxystyrene-based resin, an acid crosslinkable substance, a specific photoacid generator, and a dissolution accelerating agent.

### CITATION LIST

### Patent Document

### [Patent Document 1]

Japanese Patent No. 3655030

### SUMMARY OF INVENTION

### Technical Problem

As a result of studies by the inventors of the present invention, it was found that in a case of using a resist composition that employs an alkali-soluble polyhydroxystyrene-based resin as a base material component to form a thick resist film of the order of microns, forming a resist pattern, and carrying out wet etching, wet etching resistance may be insufficient.

On the other hand, in a case of using a resist composition that employs a novolak resin as a base material component to form a thick resist film of the order of microns and forming a resist pattern, the resolution may be insufficient.

The present invention has been made in consideration of the above circumstances, and an object of the present invention is to provide a resist composition that makes it possible to form a resist pattern having good resolution and good wet etching resistance, and a method for forming a resist pattern using the resist composition.

### Solution to Problem

In order to achieve the above-described object, the present invention employs the following configurations.

That is, a first aspect according to the present invention is a resist composition containing a polymeric compound (A1) having a constitutional unit (a10) represented by General Formula (a10-1), an acid generator (B), at least one crosslinking agent (C) selected from the group consisting of a melamine-based crosslinking agent, a urea-based crosslinking agent, an alkylene urea-based crosslinking agent, a glycoluril-based crosslinking agent, and an epoxy-based crosslinking agent, and a polyether compound (Z), in which a content of the polyether compound (Z) is less than 50 parts by mass with respect to 100 parts by mass of the polymeric compound (A1).

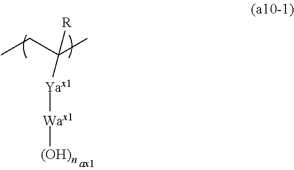

[In the formula, R represents a hydrogen atom, an alkyl group having 1 to 5 carbon atoms, or a halogenated alkyl group having 1 to 5 carbon atoms. Ya^{x1} represents a single bond or a divalent linking group. Wa^{x1} represents an aromatic hydrocarbon group which may have a substituent. nₐₓ₁ represents an integer of 1 or more.]

The second aspect according to the present invention is a method for forming a resist pattern, including a step of forming a resist film on a support using the resist composition according to the first aspect, a step of exposing the resist film, and a step of developing the exposed resist film to form a resist pattern.

### Advantageous Effects of Invention

According to the present invention, it is possible to provide a resist composition that makes it possible to form a resist pattern having good resolution and good wet etching resistance, and a method for forming a resist pattern using the resist composition.

### DESCRIPTION OF EMBODIMENTS

In the present specification and the scope of the present patent claims, the term “aliphatic” is a relative concept used with respect to the term “aromatic” and defines a group or compound that has no aromaticity.

The “alkyl group” includes a monovalent saturated hydrocarbon group that is linear, branched, or cyclic, unless otherwise specified. The same applies to the alkyl group of the alkoxy group.

The “alkylene group” includes a divalent saturated hydrocarbon group that is linear, branched, or cyclic, unless otherwise specified.

Examples of the “halogen atom” include a fluorine atom, a chlorine atom, a bromine atom, and an iodine atom.

The term “constitutional unit” means a monomer unit (monomeric unit) that constitutes a polymeric compound (a resin, a polymer, or a copolymer).

In a case where “may have a substituent” is described, both of a case where a hydrogen atom (—H) is substituted with a monovalent group and a case where a methylene group (—CH₂—) is substituted with a divalent group are included.

The “exposure” is used as a general concept that includes irradiation with any form of radiation.

The “acid decomposable group” indicates a group having an acid decomposability, in which at least parts of bonds in the structure of the acid decomposable group can be cleaved under action of acid.

Examples of the acid decomposable group having a polarity that is increased under action of acid include groups which is decomposed under action of acid to generate a polar group.

Examples of the polar group include a carboxy group, a hydroxyl group, an amino group, and a sulfo group (—SO₃H).

More specific examples of the acid decomposable group include a group obtained by protecting the above-described polar group with an acid dissociable group (for example, a group obtained by protecting a hydrogen atom of the OH-containing polar group with an acid dissociable group).

The “acid dissociable group” indicates both (i) a group having an acid dissociability, in which a bond between the acid dissociable group and an atom adjacent to the acid dissociable group can be cleaved under action of acid; and (ii) a group in which some bonds are cleaved under action of acid, and then a decarboxylation reaction occurs, thereby cleaving the bond between the acid dissociable group and the atom adjacent to the acid dissociable group.

It is necessary that the acid dissociable group that constitutes the acid decomposable group be a group that exhibits a lower polarity than the polar group generated by the dissociation of the acid dissociable group. Thus, in a case where the acid dissociable group is dissociated under action of acid, a polar group that exhibits a higher polarity than the acid dissociable group is generated, thereby increasing the polarity. As a result of the above, the polarity of the entire component (A1) is increased. By the increase in the polarity, the solubility in a developing solution relatively changes. The solubility is increased in a case where the developing solution is an alkali developing solution, whereas the solubility is decreased in a case where the developing solution is an organic developing solution.

The “base material component” is an organic compound having a film-forming ability. The organic compounds used as the base material component are roughly classified into a non-polymer and a polymer. As the non-polymer, those having a molecular weight of 500 or more and less than 4,000 are usually used. Hereinafter, a “low molecular weight compound” refers to a non-polymer having a molecular weight of 500 or more and less than 4,000. As the polymer, those having a molecular weight of 1,000 or more are usually used. Hereinafter, a “resin”, a “polymeric compound”, or a “polymer” refers to a polymer having a molecular weight of 1,000 or more. As the molecular weight of the polymer, a polystyrene-equivalent mass average molecular weight determined by gel permeation chromatography (GPC) is used.

The “constitutional unit derived from” means a constitutional unit that is formed by the cleavage of a multiple bond between carbon atoms, for example, an ethylenic double bond.

In the “acrylic acid ester”, the hydrogen atom bonded to the carbon atom at the α-position may be substituted with a substituent. The substituent (R^{αx}) that is substituted for the hydrogen atom bonded to the carbon atom at the α-position is an atom other than a hydrogen atom or a group. Further, itaconic acid diester in which the substituent (R^{αx}) is substituted with a substituent having an ester bond or an α-hydroxyacryl ester in which the substituent (R^{αx}) is substituted with a hydroxyalkyl group or a group in which a hydroxyl group thereof is modified can be mentioned as an acrylic acid ester. A carbon atom at the α-position of acrylic acid ester indicates the carbon atom bonded to the carbonyl group of acrylic acid, unless otherwise specified.

Hereinafter, an acrylic acid ester in which the hydrogen atom bonded to the carbon atom at the α-position is substituted with a substituent is also referred to as the α-substituted acrylic acid ester”.

The “derivative” includes those in which the hydrogen atom at the α-position of an object compound has been substituted with other substituents such as an alkyl group and a halogenated alkyl group; and derivatives thereof. Examples of the derivatives thereof include a derivative in which the hydrogen atom of the hydroxyl group of the object compound in which the hydrogen atom at the α-position may be substituted with a substituent is substituted with an organic group; and a derivative in which a substituent other than a hydroxyl group is bonded to the object compound in which the hydrogen atom at the α-position may be substituted with a substituent. The α-position refers to the first carbon atom adjacent to the functional group unless otherwise specified.

Examples of the substituent that is substituted for the hydrogen atom at the α-position of hydroxystyrene include the same one as R^{αx}.

In the present specification and the scope of the present patent claims, asymmetric carbon atoms may be present or enantiomers or diastereomers may be present depending on the structure represented by the chemical formula. In that case, these isomers are represented by one chemical formula. These isomers may be used alone or in the form of a mixture.

### (Resist Composition)

The resist composition according to the first aspect according to the present invention contains a polymeric compound (A1) having a constitutional unit (a10) represented by General Formula (a10-1) (hereinafter, also referred to as a “component (A1)”); an acid generator (B) (hereinafter, also referred to as a “component (B)”); at least one crosslinking agent (C) selected from the group consisting of a melamine-based crosslinking agent, a urea-based crosslinking agent, an alkylene urea-based crosslinking agent, a glycoluril-based crosslinking agent, and an epoxy-based crosslinking agent (hereinafter, also referred to as a “component (C)”); and a polyether compound (Z). In the resist composition according to the present embodiment, the content of the component (Z) is less than 50 parts by mass with respect to 100 parts by mass of the component (A1).

In a case where a resist film is formed using such a resist composition, a thick resist film (for example, a film having a film thickness of 1 μm or more) can be formed.

In a case where a resist film is formed using such a resist composition and the formed resist film is subjected to selective exposure, acid is generated at exposed portions of the resist film, and the generated acid acts on the component (A) so that the component (A) exhibits changed solubility in a developing solution, whereas the component (A) does not exhibit changed solubility in a developing solution at the unexposed portions of the resist film, thereby generating the difference in solubility in the developing solution between exposed portions and the unexposed portions of the resist film. Therefore, by subjecting the resist film to development, exposed portions of the resist film are dissolved and removed to form a positive-tone resist pattern in a case where the resist composition is a positive-tone type, whereas unexposed portions of the resist film are dissolved and removed to form a negative-tone resist pattern in a case where the resist composition is a negative-tone type.

In the present specification, a resist composition which forms a positive-tone resist pattern by dissolving and removing exposed portions of the resist film is called a positive-tone resist composition, and a resist composition which forms a negative-tone resist pattern by dissolving and removing unexposed portions of the resist film is called a negative-tone resist composition. The resist composition according to the present embodiment may be a positive-tone resist composition or a negative-tone resist composition. Further, in the resist pattern formation, the resist composition according to the present embodiment may be applied to an alkali developing process using an alkali developing solution in the developing treatment, or a solvent developing process using a developing solution containing an organic solvent (organic developing solution) in the developing treatment.

### <Component (A)>

The component (A) is a base material component that exhibits changed solubility in a developing solution under action of acid.

In the present invention, the “base material component” is an organic compound having a film-forming ability, and an organic compound having a molecular weight of 500 or more is preferably used. In a case where the molecular weight of the organic compound is 500 or more, the film-forming ability is improved, and in addition, a nano-level resist pattern is easily formed.

The organic compounds used as the base material component are roughly classified into a non-polymer and a polymer.

As the non-polymer, those having a molecular weight of 500 or more and less than 4,000 are usually used. Hereinafter, a “low molecular weight compound” refers to a non-polymer having a molecular weight of 500 or more and less than 4,000.

As the polymer, those having a molecular weight of 1,000 or more are usually used. Hereinafter, a “resin”, a “polymeric compound”, or a “polymer” refers to a polymer having a molecular weight of 1,000 or more.

As the molecular weight of the polymer, a weight average molecular weight in terms of the polystyrene equivalent value determined by gel permeation chromatography (GPC) is used.

In the resist composition according to the present embodiment, at least the polymeric compound (A1) having the constitutional unit (a10) represented by General Formula (a0-1) is used in the component (A), and a polymeric compound and/or a low molecular weight compound other than the component (A1) may be further used in combination.

In a case where a resist composition containing at least the component (A1) is used to form a resist film, and the resist film is subjected to the selective exposure, acid is generated from the component (B) in exposed portions of the resist film, for example, in a case where the resist composition contains the component (B), crosslinking occurs under the action of the acid between the components (A1) through the crosslinkable constitutional unit (a10), and as a result, the solubility of the exposed portions of the resist film in an alkali developing solution decreases. Therefore, in the resist pattern formation, in a case where a resist film formed by applying the resist composition according to the present embodiment onto a support is subjected to the selective exposure, exposed portions of the resist film change to be insoluble in an alkali developing solution, whereas unexposed portions of the resist film remain soluble in the alkali developing solution, and thus, a negative-tone resist pattern is formed by carrying out development with the alkali developing solution.

### In Regard to Component (A1)

The component (A1) is a polymeric compound having a constitutional unit (a10) represented by General Formula (a10-1).

The component (A1) is preferably a copolymer further having, in addition to the constitutional unit (a10), a constitutional unit (a11) containing an aromatic ring (excluding an aromatic ring to which a hydroxy group is bonded) in the side chain.

In addition, the component (A1) may have a constitutional unit other than the constitutional unit (a10) and the constitutional unit (a11).

In regard to constitutional unit (a10):

The constitutional unit (a10) is a constitutional unit represented by General Formula (a10-1).

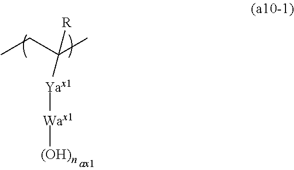

[In the formula, R represents a hydrogen atom, an alkyl group having 1 to 5 carbon atoms, or a halogenated alkyl group having 1 to 5 carbon atoms. Ya^{x1} represents a single bond or a divalent linking group. Wa^{x1} represents an aromatic hydrocarbon group which may have a substituent. nₐₓ₁ represents an integer of 1 or more.]

[In the formula, R represents a hydrogen atom, an alkyl group having 1 to 5 carbon atoms, or a halogenated alkyl group having 1 to 5 carbon atoms. Ya^{x1} represents a single bond or a divalent linking group. Wa^{x1} represents an aromatic hydrocarbon group which may have a substituent. nₐₓ₁ represents an integer of 1 or more.]

In General Formula (a10-1), R represents a hydrogen atom, an alkyl group having 1 to 5 carbon atoms, or a halogenated alkyl group having 1 to 5 carbon atoms.

The alkyl group having 1 to 5 carbon atoms as R is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group.

The halogenated alkyl group having 1 to 5 carbon atoms as R is a group obtained by substituting part or all of hydrogen atoms of an above-described alkyl group having 1 to 5 carbon atoms with a halogen atom. The halogen atom is particularly preferably a fluorine atom.

R is preferably a hydrogen atom, an alkyl group having 1 to 5 carbon atoms, or a fluorinated alkyl group having 1 to 5 carbon atoms, and in terms of industrial availability, R is more preferably a hydrogen atom, a methyl group, or trifluoromethyl group, still more preferably a hydrogen atom or a methyl group, and particularly preferably a hydrogen atom.

In General Formula (a10-1), Ya^{x1} represents a single bond or a divalent linking group.

In the chemical formulae described above, the divalent linking group as Ya^{x1} is not particularly limited, and suitable examples thereof include a divalent hydrocarbon group which may have a substituent, and a divalent linking group having hetero atoms.

Divalent Hydrocarbon Group which May have Substituent:

In a case where Ya^{x1} represents a divalent hydrocarbon group which may have a substituent, the hydrocarbon group may be an aliphatic hydrocarbon group or an aromatic hydrocarbon group.

### Aliphatic Hydrocarbon Group as Ya^{x1}

The aliphatic hydrocarbon group indicates a hydrocarbon group that has no aromaticity. The aliphatic hydrocarbon group may be saturated or unsaturated. In general, it is preferable that the aliphatic hydrocarbon group is saturated.

Examples of the aliphatic hydrocarbon group include a linear or branched aliphatic hydrocarbon group, and an aliphatic hydrocarbon group containing a ring in the structure thereof.

### Linear or Branched Aliphatic Hydrocarbon Group

The linear aliphatic hydrocarbon group preferably has 1 to 10 carbon atoms, more preferably 1 to 6 carbon atoms, still more preferably 1 to 4 carbon atoms, and most preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group has preferably 2 to 10 carbon atoms, more preferably 3 to 6 carbon atoms, still more preferably 3 or 4 carbon atoms, and most preferably 3 carbon atoms.

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—. and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The linear or branched aliphatic hydrocarbon group may or may not have a substituent. Examples of the substituent include a fluorine atom, a fluorinated alkyl group having 1 to 5 carbon atoms, which has been substituted with a fluorine atom, and a carbonyl group.

### Aliphatic Hydrocarbon Group Containing Ring in Structure Thereof

Examples of the aliphatic hydrocarbon group containing a ring in the structure thereof include a cyclic aliphatic hydrocarbon group which may contain a substituent containing a hetero atom in the ring structure thereof (a group obtained by removing two hydrogen atoms from an aliphatic hydrocarbon ring), a group obtained by bonding a cyclic aliphatic hydrocarbon group to the terminal of a linear or branched aliphatic hydrocarbon group, and a group obtained by interposing a cyclic aliphatic hydrocarbon group in a linear or branched aliphatic hydrocarbon group. Examples of the linear or branched aliphatic hydrocarbon group include the same ones as those described above.

The cyclic aliphatic hydrocarbon group preferably has 3 to 20 carbon atoms and more preferably 3 to 12 carbon atoms.

The cyclic aliphatic hydrocarbon group may be a polycyclic group or a monocyclic group. The monocyclic alicyclic hydrocarbon group is preferably a group obtained by removing two hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing two hydrogen atoms from a polycycloalkane, and the polycycloalkane is preferably a group having 7 to 12 carbon atoms. Specific examples of the polycyclic alicyclic hydrocarbon group include adamantane, norbornane, isobornane, tricyclodecane, and tetracyclododecane.

The cyclic aliphatic hydrocarbon group may have or may not have a substituent. Examples of the substituent include an alkyl group, an alkoxy group, a halogen atom, a halogenated alkyl group, a hydroxyl group, and a carbonyl group.

The alkyl group as the substituent is preferably an alkyl group having 1 to 5 carbon atoms, and more preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and still more preferably a methoxy group or an ethoxy group.

The halogen atom as the substituent is preferably a fluorine atom.

Examples of the halogenated alkyl group as the substituent include a group obtained by substituting part or all of hydrogen atoms in the above-described alkyl group with the above-described halogen atom.

In the cyclic aliphatic hydrocarbon group, part of carbon atoms constituting the ring structure thereof may be substituted with a substituent containing a hetero atom. The substituent containing a hetero atom is preferably —O—, —C(═O)—O—, —S—, —S(═O)₂—, or —S(═O)₂—O—.

### Aromatic Hydrocarbon Group as Ya^{x1}

The aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms. However, the number of carbon atoms in the substituent is not included in the number of carbon atoms.

Specific examples of the aromatic ring include aromatic hydrocarbon rings such as benzene, naphthalene, anthracene, and phenanthrene; and an aromatic heterocyclic ring obtained by substituting part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group include a group (an arylene group or a heteroarylene group) obtained by removing two hydrogen atoms from the above-described aromatic hydrocarbon ring or the above-described aromatic heterocyclic ring; a group obtained by removing two hydrogen atoms from an aromatic compound having two or more aromatic rings (such as biphenyl or fluorene); and a group (for example, a group obtained by further removing one hydrogen atom from an aryl group in arylalkyl groups such as a benzyl group, a phenethyl group, a 1-naphthylmethyl group, a 2-naphthylmethyl group, a 1-naphthylethyl group, or a 2-naphthylethyl group) obtained by substituting one hydrogen atom of a group (an aryl group or a heteroaryl group) obtained by removing one hydrogen atom from the above aromatic hydrocarbon ring or the above aromatic heterocyclic ring, with an alkylene group. The alkylene group bonded to the aryl group or the heteroaryl group preferably has 1 to 4 carbon atoms, more preferably 1 or 2 carbon atoms, and particularly preferably 1 carbon atom.

With respect to the aromatic hydrocarbon group, the hydrogen atom contained in the aromatic hydrocarbon group may be substituted with a substituent. For example, the hydrogen atom bonded to the aromatic ring in the aromatic hydrocarbon group may be substituted with a substituent. Examples of substituents include an alkyl group, an alkoxy group, a halogen atom, a halogenated alkyl group, and a hydroxyl group.

The alkyl group as the substituent is preferably an alkyl group having 1 to 5 carbon atoms, and more preferably a methyl group, an ethyl group, a propyl group, an n-butyl group, or a tert-butyl group.

Examples of the alkoxy group, the halogen atom, and the halogenated alkyl group, as the substituent, include the same groups as those exemplified as the substituent that is substituted for a hydrogen atom contained in the cyclic aliphatic hydrocarbon group.

### Divalent Linking Group Containing Hetero Atom:

In a case where Ya^{x1} represents a divalent linking group containing a hetero atom, preferred examples of the linking group include —O—, —C(═O)—O—, —O—C(═O)—, —C(═O)—, —O—C(═O)—O—, —C(═O)—NH—, —NH—, —NH—C(═NH)— (H may be substituted with a substituent such as an alkyl group, an acyl group, or the like), —S—, —S(═O)₂—, —S(═O)₂—O—, and a group represented by General Formula —Y²¹—O—Y²²—, —Y²¹—O—, —Y²¹—C(═O)—O—, —C(═O)—O—Y²¹—, —[Y²¹—C(═O)—O]_{m″}—Y²²—, —Y²¹—O—C(═O)—Y²²— or —Y²¹—S(═O)₂—O—Y²²— [in the formulae, Y²¹ and Y²² each independently represent a divalent hydrocarbon group which may have a substituent, 0 represents an oxygen atom, and m″ represents an integer in a range of 0 to 3].

In a case where the divalent linking group containing a hetero atom is —C(═O)—NH—, —C(═O)—NH—C(═O)—, —NH—, or —NH—C(═NH)—, H may be substituted with a substituent such as an alkyl group, an acyl group, or the like. The substituent (an alkyl group, an acyl group, or the like) preferably has 1 to 10 carbon atoms, more preferably 1 to 8 carbon atoms, and particularly preferably 1 to 5 carbon atoms.

In General Formulae —Y²¹—O—Y²—, —Y²¹—O—, —Y²¹—C(═O)—O—, —C(═O)—O—Y²¹—, —[Y²¹—C(═O)—O]_{m″}—Y²²—, —Y²¹—O—C(═O)—Y²²—, and —Y²¹—S(═O)₂—O—Y²²—, Y², and Y²² each independently represent a divalent hydrocarbon group which may have a substituent. Examples of the divalent hydrocarbon group include the same one as “the divalent hydrocarbon groups which may have a substituent”, described in the explanation of the above-described divalent linking group as Ya^{x1}.

Y²¹ is preferably a linear aliphatic hydrocarbon group, more preferably a linear alkylene group, still more preferably a linear alkylene group having 1 to 5 carbon atoms, and particularly preferably a methylene group or an ethylene group.

Y²² is preferably a linear or branched aliphatic hydrocarbon group and more preferably a methylene group, an ethylene group, or an alkylmethylene group. The alkyl group in the alkylmethylene group is preferably a linear alkyl group having 1 to 5 carbon atoms, more preferably a linear alkyl group having 1 to 3 carbon atoms, and most preferably a methyl group.

In the group represented by General Formula —[Y²¹—C(═O)—O]_{m″}—Y²²—, m″ represents an integer in a range of 0 to 3, preferably an integer in a range of 0 to 2, more preferably 0 or 1, and particularly preferably 1. In other words, it is particularly preferable that the group represented by General Formula —[Y²¹—C(═O)—O]_{m′}—Y²²— represents a group represented by General Formula —Y²¹—C(═O)—O—Y²²—. Among these, a group represented by General Formula —(CH₂)_{a′}—C(═O)—O—(CH₂)_{b′}— is preferable. In the formula, a′ represents an integer in a range of 1 to 10, preferably an integer in a range of 1 to 8, more preferably an integer in a range of 1 to 5, still more preferably 1 or 2, and most preferably 1. b′ represents an integer in a range of 1 to 10, preferably an integer in a range of 1 to 8, more preferably an integer in a range of 1 to 5, still more preferably 1 or 2, and most preferably 1.

Among the above, Ya^{x1} is preferably a single bond, an ester bond [—C(═O)—O—, —O—C(═O)—], an ether bond (—O—), a linear or branched alkylene group, or a combination thereof, and more preferably a single bond or an ester bond [—C(═O)—O—, —O—C(═O)—].

In General Formula (a10-1), Wa^{x1} represents an aromatic hydrocarbon group which may have a substituent.

Examples of the aromatic hydrocarbon group as Wa^{x1} include a group obtained by removing (nₐₓ₁+1) hydrogen atoms from an aromatic ring which may have a substituent. Here, the aromatic ring is not particularly limited as long as it is a cyclic conjugated system having (4n+2) π electrons, and may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms. Specific examples of the aromatic ring include aromatic hydrocarbon rings such as benzene, naphthalene, anthracene, and phenanthrene; and aromatic heterocyclic rings obtained by substituting part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Examples of the aromatic hydrocarbon group as Wa^{x1} also include a group obtained by removing (nₐₓ₁+1) hydrogen atoms from an aromatic compound including an aromatic ring (for example, biphenyl or fluorene) which may have two or more substituents.

Among the above, Wa^{x1} is preferably a group obtained by removing (nₐₓ₁+1) hydrogen atoms from benzene, naphthalene, anthracene, or biphenyl, more preferably a group obtained by removing (nₐₓ₁+1) hydrogen atoms from benzene or naphthalene, and still more preferably a group obtained by removing (nₐₓ₁+1) hydrogen atoms from benzene.

The aromatic hydrocarbon group as Wa^{x1} may or may not have a substituent. Examples of the substituent include an alkyl group, an alkoxy group, a halogen atom, and a halogenated alkyl group. Examples of the alkyl group, the alkoxy group, the halogen atom, and the halogenated alkyl group, as the substituent, include the same ones as those described as the above-described substituent of the cyclic aliphatic hydrocarbon group as Ya^{x1}. The substituent is preferably a linear or branched alkyl group having 1 to 5 carbon atoms, more preferably a linear or branched alkyl group having 1 to 3 carbon atoms, still more preferably an ethyl group or a methyl group, and particularly preferably a methyl group. The aromatic hydrocarbon group as Waₓ₁ preferably has no substituent.

In General Formula (a10-1), nₐₓ₁ represents an integer of 1 or more, preferably an integer in a range of 1 to 10, more preferably an integer in a range of 1 to 5, still more preferably 1, 2, or 3, and particularly preferably 1 or 2.

Specific examples of the constitutional unit (a10) represented by General Formula (a10-1) are shown below.

In the formulae shown below, Ra represents a hydrogen atom, a methyl group, or a trifluoromethyl group.

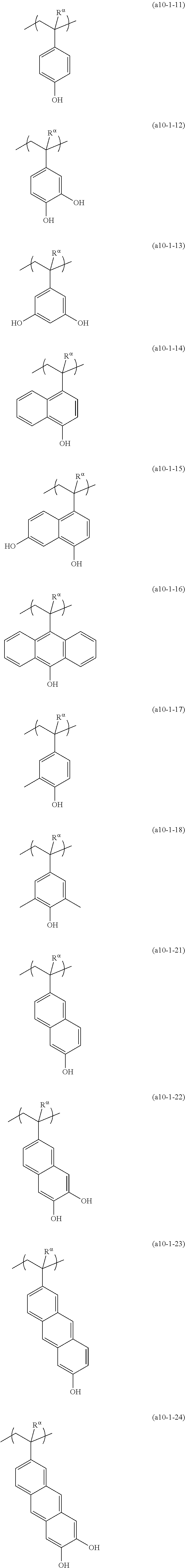

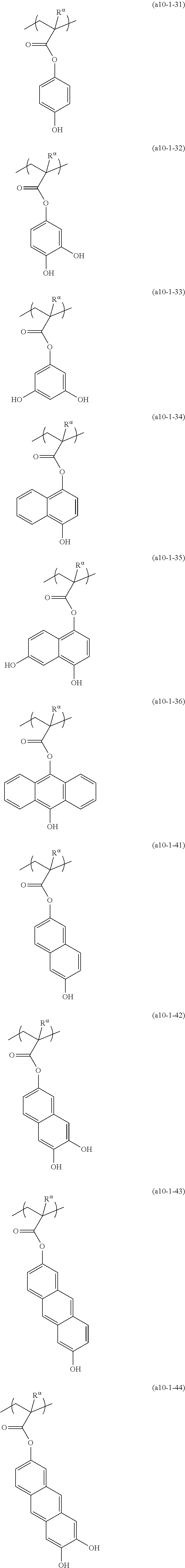

The constitutional unit (a10) contained in the component (A1) may be one kind or may be two or more kinds.

The proportion of the constitutional unit (a10) in the component (A1) is preferably in a range of 70% to 99% by mole, more preferably in a range of 75% to 99% by mole, still more preferably in a range of 80% to 99% by mole, and particularly preferably in a range of 85% to 95% by mole, with respect to the total (100% by mole) of all constitutional units constituting the component (A1).

In a case where the proportion of the constitutional unit (a10) is set to be equal to or larger than the lower limit value, development characteristics and lithography characteristics are further improved. On the other hand, in a case of being set to be equal to or smaller than the upper limit value, balance with other constitutional units is obtained easily.

In regard to constitutional unit (a11):

The component (A1) is preferably a copolymer further having, in addition to the above-described constitutional unit (a10), the constitutional unit (a11) derived from a compound containing an aromatic ring (excluding an aromatic ring to which a hydroxy group is bonded) in the side chain.

Suitable examples of the compound containing an aromatic ring (excluding an aromatic ring to which a hydroxy group is bonded) in the side chain include a compound represented by General Formula (a11-1).

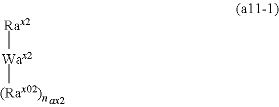

[In General Formula (a11-1), Ra^{x2} represents a polymerizable group-containing group. Wa^{x2} represents an (nₐₓ₂+1)-valent aromatic hydrocarbon group. However, Ra^{x2} and Wa^{x2} may form a condensed ring structure. Ra^{x02} represents a substituent that is substituted for a hydrogen atom constituting Wa^{x2} (an aromatic hydrocarbon group). nₐₓ₂ represents an integer in a range of 0 to 3. In a case where nₐₓ₂ represents 2 or more, a plurality of Ra^{x02}'s may be bonded together to form a ring structure.]

In General Formula (a11-1), Ra^{x2} represents a polymerizable group-containing group.

The “polymerizable group” as Ra^{x2} is a group that enables a compound having the polymerizable group to be polymerized by radical polymerization or the like, and includes a group containing a multiple bond between carbon atoms, such as an ethylenic double bond.

Examples of the polymerizable group include a vinyl group, an allyl group, acryloyl group, a methacryloyl group, a fluorovinyl group, a difluorovinyl group, a trifluorovinyl group, a difluorotrifluoromethylvinyl group, a trifluoroallyl group, a perfluoroallyl group, a trifluoromethylacryloyl group, a nonylfluorobutylacryloyl group, a vinyl ether group, a fluorine-containing vinyl ether group, an allyl ether group, a fluorine-containing allyl ether group, a styryl group, and a vinylnaphthyl group, a fluorine-containing styryl group, a fluorine-containing vinylnaphthyl group, a norbornyl group, a fluorine-containing norbornyl group, and a silyl group.

The “polymerizable group-containing group” may be a group composed of only a polymerizable group, or a group composed of a polymerizable group and a group other than the polymerizable group. Examples of the group other than the polymerizable group include a divalent hydrocarbon group which may have a substituent and a divalent linking group containing a hetero atom.

Suitable examples of Ra^{x2} include a group represented by a chemical formula: CH₂═C(R)—Ya^{x0}-. In this chemical formula, R represents a hydrogen atom, an alkyl group having 1 to 5 carbon atoms, or a halogenated alkyl group having 1 to 5 carbon atoms, and Ya^{x0} represents a divalent linking group.

In General Formula (a11-1), Wa^{x2} represents a (nₐₓ₂+1)-valent aromatic hydrocarbon group, and examples thereof include the same one as Wa^{x1} in (a10-1) described above.

However, Ra^{x2} and Wa^{x2} may form a condensed ring structure.

In a case where Ra^{x2} and Wa^{x2} form a condensed ring structure, the condensed ring structure includes an aromatic ring derived from Wa^{x2}. In addition, the multiple bond between carbon atoms of the polymerizable group derived from Ra^{x2} is cleaved to form the main chain of the component (A1). That is, part of carbon atoms constituting the condensed ring constitute the main chain of component (A1).

In General Formula (a11-1), Ra^{x02} represents a substituent that is substituted for a hydrogen atom constituting Wa^{x2} (an aromatic hydrocarbon group).

Examples of the substituent as Ra^{x02} include an alkyl group, an alkoxy group, and an acyloxy group.

The alkyl group as a substituent as Ra^{x02} is preferably an alkyl group having 1 to 5 carbon atoms, and it is more preferably a methyl group, an ethyl group, a propyl group, an n-butyl group, or a tert-butyl group.

The alkoxy group a substituent as Ra^{x02} is preferably an alkoxy group having 1 to 5 carbon atoms, more preferably a methoxy group, an ethoxy group, an n-propoxy group, an iso-propoxy group, an n-butoxy group, or a tert-butoxy group, and particularly preferably a methoxy group or an ethoxy group.

The acyloxy group as a substituent as Ra^{x02} preferably has 2 to 6 carbon atoms, more preferably CH₃C(═O)—O— (an acetoxy group), C₂H5C(═O)—O—, and particularly preferably CH₃C(═O)—O— (an acetoxy group).

In General Formula (a11-1), nₐₓ₂ represents an integer in a range of 0 to 3, preferably 0,1, or 2, and more preferably 0 or 1.

In a case where nₐₓ2 represents 2 or more, a plurality of Ra^{x02}'s may be bonded together to form a ring structure. The ring structure formed here may be a hydrocarbon ring or a heterocyclic ring. Examples of the ring structure include a ring structure formed by two Ra^{x02} bonded to the same aromatic ring in Wa^{x2} and one side (a bond between carbon atoms) of this aromatic ring (Wa^{x2}) to which the two Ra^{x02}'s are bonded.

Suitable examples of such a constitutional unit (a11) include constitutional units each represented by General Formulae (a11-u1-1) to (a11-u1-6).

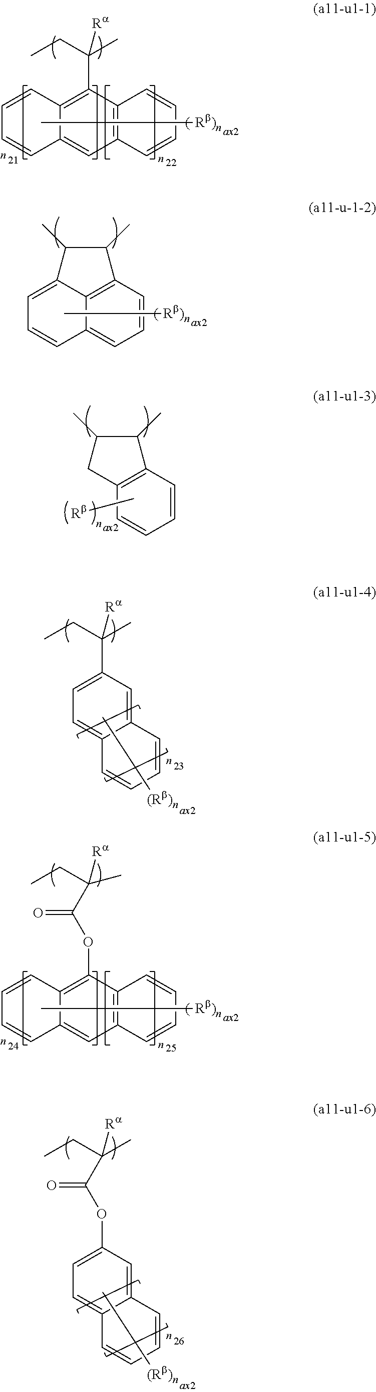

[In the formula, R^{α} represents a hydrogen atom, a methyl group, or a trifluoromethyl group. R^{β} represents an alkyl group, an alkoxy group, or an acyloxy group. nₐₓ₂ represents an integer in a range of 0 to 3. In a case where nₐₓ₂ represents 2 or more, a plurality of R^{β}'s may be bonded together to form a ring structure. n₂₁, n₂₂, n₂₄, and n₂₅ each independently represent 0 or 1. n₂₃ and n₂₆ each independently represent 1 or 2.]

In General Formulae (a11-u1-1) to (a11-u1-6) described above, the alkyl group, alkoxy group, and acyloxy group as RP are the same as the alkyl group, the alkoxy group, and the acyloxy group, which are exemplified as the substituents as Ra^{x02} in General Formula (a11-1).

Specific examples of the constitutional unit (the constitutional unit (a11)) derived from the compound represented by General Formula (a11-1) are shown below.

In the formulae shown below, R^{α} represents a hydrogen atom, a methyl group, or a trifluoromethyl group.

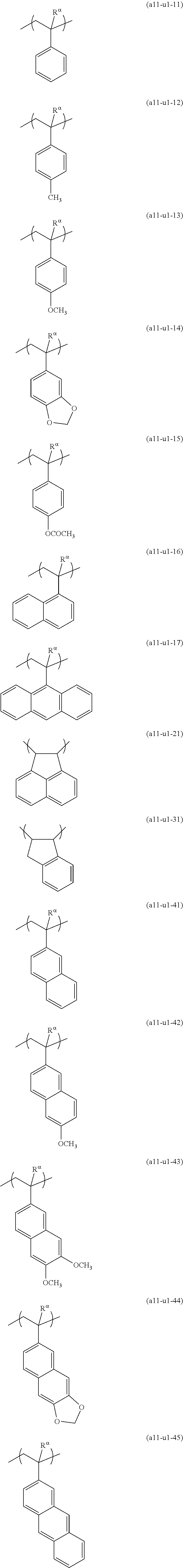

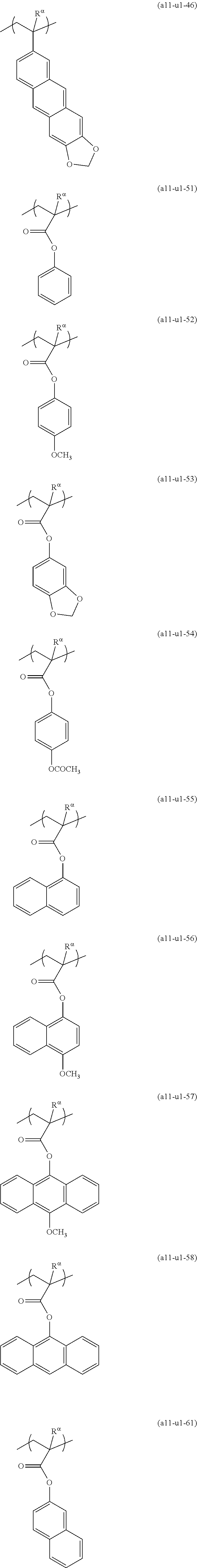

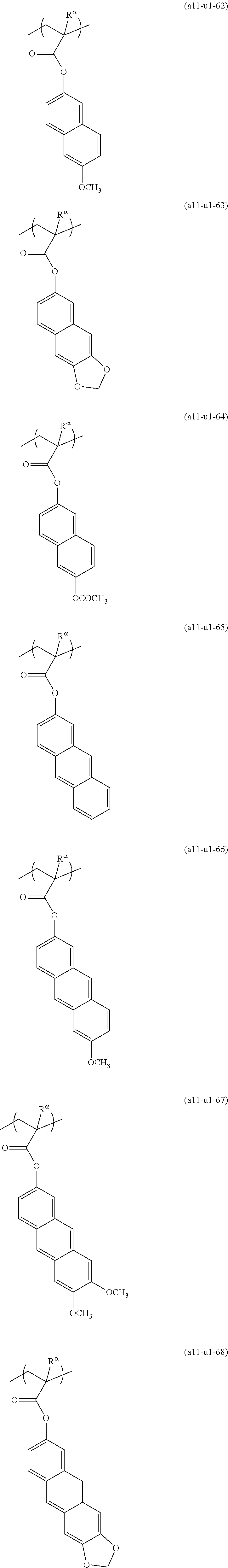

Among those exemplified above, the constitutional unit (a11) is preferably at least one selected from the group consisting of constitutional units each represented by General Formulae (a11-u1-1) to (a11-u1-3) and more preferably constitutional units each represented by General Formula (a11-u1-1).

Among these, the constitutional unit (a11) is preferably a constitutional unit represented by any one of Chemical Formula (a11-u1-11), (a11-u1-21), or (a11-u1-31).

The constitutional unit (a11) contained in the component (A1) may be one kind or may be two or more kinds.

In a case where the component (A1) has the constitutional unit (a11), the proportion of the constitutional unit (a11) in the component (A1) is preferably in a range of 1% to 30% by mole, more preferably in a range of 1% to 25% by mole, still more preferably in a range of 1% to 20% by mole, and particularly preferably in a range of 5% to 15% by mole, with respect to the total (100% by mole) of all constitutional units constituting the component (A1).

In a case where the proportion of the constitutional unit (a11) is set to be equal to or larger than the lower limit value, etching resistance and lithography characteristics are further improved. On the other hand, in a case of being set to be equal to or smaller than the upper limit value, balance with other constitutional units is obtained easily.

### <<Other Constitutional Units>>

The component (A1) may have a constitutional unit other than the constitutional unit (a10) and the constitutional unit (a11).

Examples of compounds from which such other constitutional units are derived include monocarboxylic acids such as acrylic acid, methacrylic acid, and crotonic acid; dicarboxylic acids such as maleic acid, fumaric acid, and itaconic acid; methacrylic acid derivatives having a carboxy group and an ester bond, such as 2-methacryloyloxyethyl succinic acid, 2-methacryloyloxyethyl maleic acid, 2-methacryloyloxyethyl phthalic acid, and 2-methacryloxyethyl hexahydrophthalic acid; (meth)acrylic acid alkyl esters such as methyl (meth)acrylate, ethyl (meth)acrylate, and butyl (meth)acrylate; (meth)acrylic acid hydroxyalkyl esters such as 2-hydroxyethyl (meth)acrylate and 2-hydroxypropyl (meth)acrylate; (meth)acrylic acid aryl esters such as phenyl (meth)acrylate and benzyl (meth)acrylate; dicarboxylic acid diesters such as diethyl maleate and dibutyl fumarate; vinyl group-containing aliphatic compounds such as vinyl acetate; conjugate diolefins such as butadiene and isoprene; nitrile group-containing polymerizable compound such as acrylonitrile and methacrylonitrile; chlorine-containing polymerizable compounds such as vinyl chloride and vinylidene chloride; amide bond-containing polymerizable compounds such as acrylamide and methacrylamide; and epoxy group-containing polymerizable compounds.

In the resist composition according to the present embodiment, the component (A) contains the polymeric compound (A1) (the component (A1)) having the constitutional unit (a10).

Preferred examples of the component (A1) include a polymeric compound having at least the constitutional unit (a10). Suitable examples of the component (A1) include a polymeric compound (a homopolymer consisting of the constitutional unit (a10)) having a repeating structure of the constitutional unit (a10); and a polymeric compound having a repeating structure of the constitutional unit (a10) and the constitutional unit (a11).

The weight average molecular weight (Mw) (in terms of the polystyrene equivalent value determined by gel permeation chromatography (GPC)) of the component (A1), which is not particularly limited, is preferably in a range of 500 to 50,000, more preferably in a range of 1,000 to 30,000, and still more preferably in a range of 2,000 to 20,000.

In a case where Mw of the component (A1) is equal to or smaller than the upper limit value of this preferred range, the sufficient solubility in the resist solvent is exhibited in a case of being used as a resist. On the other hand, in a case where Mw thereof is equal to or larger than the lower limit value of this preferred range, the dry etching resistance and the cross-sectional shape of the resist pattern become more excellent.

The dispersity (Mw/Mn) of the component (A1) is not particularly limited; however, it is preferably in a range of 1.0 to 4.0, more preferably in a range of 1.0 to 3.0, and particularly preferably in a range of 1.0 to 2.5. In addition, Mn shows a number average molecular weight.

The component (A1) can be produced by dissolving, in a polymerization solvent, each monomer from which the constitutional unit is derived, adding thereto a radical polymerization initiator such as azobisisobutyronitrile (AlBN) or dimethyl azobisisobutyrate (for example, V-601) to carry out polymerization.

Alternatively, the component (A1) can be produced by dissolving, in a polymerization solvent, a monomer from which the constitutional unit (a10) is derived and, as necessary, a monomer from which a constitutional unit other than the constitutional unit (a10) is derived, adding thereto a radical polymerization initiator such as described above to carry out polymerization, and then carrying out a deprotection reaction.

Further, a —C(CF₃)₂—OH group may be introduced into the terminal thereof during the polymerization using a chain transfer agent such as HS—CH₂—CH₂—CH₂—C(CF₃)₂—OH in combination. As described above, a copolymer into which a hydroxyalkyl group, formed by substitution of part of hydrogen atoms in the alkyl group with fluorine atoms, has been introduced is effective for reducing development defects and reducing line edge roughness (LER: uneven irregularities of a line side wall).

In addition, the component (A1) can be produced according to an anionic polymerization method by using, as a polymerization initiator, an organic alkali metal such as n-butyl lithium, s-butyl lithium, t-butyl lithium, ethyl lithium, ethyl sodium, 1,1-diphenylhexyl lithium, or 1,1-diphenyl-3-methylpentyl lithium.

### In Regard to Component (A2)

In the resist composition according to the present embodiment, a base material component (hereinafter, referred to as a “component (A2)”) that exhibits changed solubility in a developing solution under action of acid, which does not correspond to the component (A1), may be used in combination as the component (A).

The component (A2) is not particularly limited and may be freely selected and used from a large number of base material components for the chemical amplification-type resist composition, which are known in the related art.

As the component (A2), a polymeric compound or a low molecular weight compound may be used alone or in a combination of two or more kinds thereof.

The proportion of the component (A1) in the component (A) is preferably 25% by mass or more, more preferably 50% by mass or more, still more preferably 75% by mass or more, and may be 100% by mass with respect to the total mass of the component (A). In a case where the proportion is 25% by mass or more, a resist pattern having various excellent lithography characteristics such as high sensitivity, resolution, and roughness amelioration can be easily formed.

The content of the component (A) in the resist composition according to the present embodiment may be adjusted depending on the resist film thickness to be formed.

### <<Acid Generator Component (B)>>

The component (B) is not particularly limited, and those which have been proposed so far as an acid generator for a chemical amplification-type resist composition in the related art can be used.

In the present embodiment, the component (B) preferably contains an acid generator (B0) represented by General Formula (b0-1) (hereinafter, referred to as a “component (B0)”).

### In Regard to Component (B0)

The component (B0) is an acid generator represented by General Formula (b0-1).

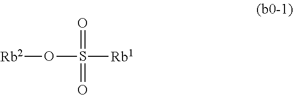

[In the formula, Rb¹ represents an organic group. Rb² represents a group represented by General Formula (b0-r-1) or General Formula (b0-r-2).]

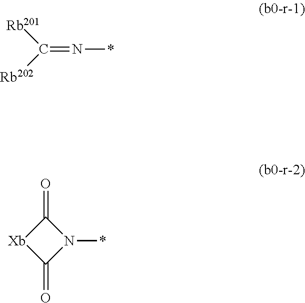

[In General Formula (b0-r-1), Rb²⁰¹ and Rb²⁰² each independently represent an organic group. * represents a bonding site. In General Formula (b0-r-2), Xb represents a group that forms a cyclic group having a cyclic imide structure, together with —(O═)C—N—C(═O)—. * represents a bonding site.]

In the present embodiment, the component (B0) is not particularly limited as long as it is a compound represented by General Formula (b0-1), and examples thereof include at least one compound selected from the group consisting of General Formulae (b0-1-1) to (b0-1-6).

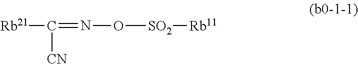

[In the formula, Rb¹¹ and Rb²¹ each independently represent a non-aromatic group.]

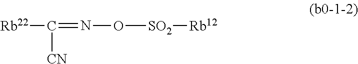

[In the formula, Rb¹² represents an alkyl group or a halogenated alkyl group. Rb²² represents an aromatic group.]

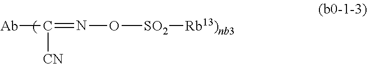

[In the formula, Rb¹³ represents a hydrocarbon group which may have a substitution. nb3 represents 2 or 3. Ab represents a divalent or trivalent organic group.]

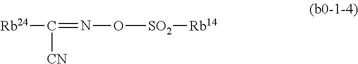

[In the formula, Rb¹⁴ represents an aromatic polycyclic hydrocarbon group, a saturated or unsaturated non-aromatic polycyclic hydrocarbon group, or a group of a substituted derivative thereof. Rb²⁴ represents an inert organic group.]

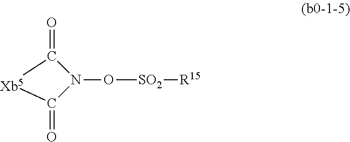

[In the formula, Rb¹⁵ represents a substituted or unsubstituted monovalent saturated hydrocarbon group, an unsaturated hydrocarbon group, or an aromatic group. Xb⁵ represents a group that forms a cyclic group having a cyclic imide structure, together with —(O═)C—N—C(═O)—.]

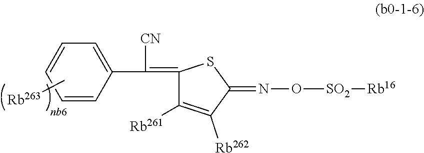

[In the formula, Rb¹⁶ represents an alkyl group which may have a substituent or an aromatic hydrocarbon group which may have a substituent. Rb²⁶¹ to Rb²⁶³ each independently represent a halogen atom, an alkyl group having 1 to 6 carbon atoms, or an alkoxy group having 1 to 6 carbon atoms. nb6 represents an integer in a range of 0 to 5.]

In General Formula (b0-1-1), examples of each of the non-aromatic groups as Rb¹¹ and Rb¹² include an alkyl group, a halogenoalkyl group, an alkenyl group, a cycloalkyl group, a cycloalkenyl group, an alkoxy group, a cycloalkoxy group, and an adamantyl group.

The alkyl group as Rb¹¹ and Rb¹² is preferably a linear or branched alkyl group having 1 to 12 carbon atoms, and examples thereof include a methyl group, an ethyl group, an n-propyl group, an isopropyl group, an n-butyl group, an isobutyl group, a sec-butyl group, a tert-butyl group, an n-pentyl group, an n-octyl group, and an n-dodecyl group.

The number of halogen atoms in the halogenoalkyl group as Rb¹¹ and Rb¹² is not particularly limited, where one halogen atom may be introduced, or a plurality of halogen atoms may be introduced. In addition, the halogen atom may be any one of a fluorine atom, a chlorine atom, a bromine atom, or an iodine atom. This halogenoalkyl group is preferably a halogenoalkyl group having 1 to 4 carbon atoms, for example, a chloromethyl group, a trichloromethyl group, a trifluoromethyl group, or a 2-bromopropyl group.

The alkenyl group as Rb¹¹ and Rb¹² is preferably a linear or branched alkenyl group having 2 to 6 carbon atoms, for example, a vinyl group, a 1-propenyl group, an isopropenyl group, or a 2-butenyl group.

The cycloalkyl group as Rb¹¹ and Rb¹² is preferably a cycloalkyl group having 5 to 12 carbon atoms, for example, a cyclopentyl group, a cyclohexyl group, a cyclooctyl group, or a cyclododecyl group, and the cycloalkenyl group is preferably a cycloalkenyl group having 4 to 8 carbon atoms, for example, a 1-cyclobutenyl group, a 1-cyclopentenyl group, a 1-cyclohexenyl group, a 1-cycloheptenyl group, or a 1-cyclooctenyl group.

The alkoxy group as Rb¹¹ and Rb¹² is preferably an alkoxy group having 1 to 8 carbon atoms, for example, a methoxy group, an ethoxy group, a propoxy group, a butoxy group, or a pentoxy group.

The cycloalkoxy group as Rb¹¹ and Rb¹² is preferably a cycloalkoxy group having 5 to 8 carbon atoms, for example, a cyclopentoxy group or a cyclohexyloxy group.

In General Formula (b0-1-1), Rb¹¹ is preferably an alkyl group, a halogenoalkyl group, or a cycloalkyl group, or particularly an alkyl group. Rb²¹ is preferably an alkyl group, a cycloalkyl group, or a cycloalkenyl group, or particularly a cycloalkenyl group. Among the above, it is more preferable that Rb¹¹ is an alkyl group having 1 to 4 carbon atoms and Rb²¹ is a cyclopentenyl group.

Specific examples of the compound represented by General Formula (b0-1-1) include α-(methylsulfonyloxyimino)-1-cyclopentenylacetonitrile, α-(methylsulfonyloxyimino)-1-cyclohexenylacetonitrile, α-(methylsulfonyloxyimino)-1-cycloheptenylacetonitrile, α-(methylsulfonyloxyimino)-1-cyclooctenylacetonitrile, α-(trifluoromethylsulfonyloxyimino)-1-cyclopentenylacetonitrile, α-(trifluoromethylsulfonyloxyimino)-cyclohexylacetonitrile, α-(ethylsulfonyloxyimino)-ethylacetonitrile, α-(propylsulfonyloxyimino)-propylacetonitrile, α-(cyclohexylsulfonyloxyimino)-cyclopentylacetonitrile, α-(cyclohexylsulfonyloxyimino)-cyclohexylacetonitrile, α-(cyclohexylsulfonyloxyimino)-1-cyclopentenylacetonitrile, α-(ethylsulfonyloxyimino)-1-cyclopentenylacetonitrile, α-(isopropylsulfonyloxyimino)-1-cyclopentenylacetonitrile, α-(n-butylsulfonyloxyimino)-1-cyclopentenylacetonitrile, α-(ethylsulfonyloxyimino)-1-cyclohexenylacetonitrile, α-(isopropylsulfonyloxyimino)-1-cyclohexenylacetonitrile, and α-(n-butylsulfonyloxyimino)-1-cyclohexenylacetonitrile.

In General Formula (b0-1-2), the alkyl group as Rb¹² is a linear or branched alkyl group having 1 to 4 carbon atoms, and examples thereof include a methyl group, an ethyl group, an n-propyl group, an isopropyl group, an n-butyl group, an isobutyl group, a sec-butyl group, and a tert-butyl group.

Examples of the halogenated alkyl group as Rb¹² include halogenated alkyl groups having 1 to 4 carbon atoms, for example, a chloromethyl group, a trichloromethyl group, a trifluoromethyl group, and a 2-bromopropyl group.

In General Formula (b0-1-2), the aromatic group as Rb²² means a group that exhibits physical and chemical properties specific to aromatic compounds, and examples thereof include a phenyl group, a naphthyl group, a furyl group, and a thienyl group. In the aromatic group as Rb²², part of hydrogen atoms of the aromatic ring constituting the aromatic group may be substituted with a substituent. Examples of the substituent include a halogen atom, an alkyl group, an alkoxy group, and a nitro group.

Specific examples of the compound represented by General Formula (b0-1-2) include α-(methylsulfonyloxyimino)-phenylacetonitrile, α-(methylsulfonyloxyimino)-4-methoxyphenylacetonitrile, α-(methylsulfonyloxyimino)-4-methylphenylacetonitrile, α-(trifluoromethylsulfonyloxyimino)-phenylacetonitrile, α-(trifluoromethylsulfonyloxyimino)-4-methoxyphenylacetonitrile, α-(ethylsulfonyloximino)-4-methoxyphenylacetonitrile, α-(propylsulfonyloxyimino)-4-methylphenylacetonitrile, and α-(methylsulfonyloxyimino)-4-bromophenylacetonitrile.

In General Formula (b0-1-3), examples of the hydrocarbon group as Rb¹³ include an aromatic group and a non-aromatic hydrocarbon group. Here, the aromatic group preferably has 6 to 14 carbon atoms, and examples thereof include aromatic hydrocarbon groups such as a phenyl group, a tolyl group, a methoxyphenyl group, a xylyl group, a biphenyl group, a naphthyl group, and an anthryl group, and heterocyclic groups such as a furanyl group, a pyridyl group, and a quinolyl group. In addition, the non-aromatic hydrocarbon groups include hydrocarbon groups that do not have a ring exhibiting aromaticity, such as a benzene ring, a naphthalene ring, a furan ring, a thiophene ring, or a pyridine ring, for example, an aliphatic hydrocarbon group and an alicyclic hydrocarbon group, such as an alkyl group, an alkenyl group, a cycloalkyl group, and a cycloalkenyl group. Although the alkyl group and alkenyl group may be linear or branched, they preferably have 1 to 12 carbon atoms, and the cycloalkyl group and cycloalkenyl group preferably have 4 to 12 carbon atoms. Examples of this alkyl group include a methyl group, an ethyl group, a propyl group, an isopropyl group, an n-butyl group, a sec-butyl group, a tert-butyl group, an n-pentyl group, an n-octyl group, and an n-dodecyl group, examples of the alkenyl group include an ethenyl group, a propenyl group, a butenyl group, a butadienyl group, a hexenyl group, and an octadienyl group, examples of the cycloalkyl group include cyclopentyl group, a cyclohexyl group, a cyclooctyl group, and a cyclododecyl group, and examples of the cycloalkenyl group include a 1-cyclobutenyl group, a 1-cyclopentenyl group, a 1-cyclohexenyl group, a 1-cycloheptenyl group, and a 1-cyclooctenyl group.

In General Formula (b0-1-3), the hydrocarbon group as Rb¹³ may have a substituent. Examples of the substituent include a halogen atom, a hydroxyl group, an alkoxy group, and an acyl group.

In General Formula (b0-1-3), examples of the divalent or trivalent organic group as Ab includes a divalent or trivalent aliphatic hydrocarbon group and an aromatic hydrocarbon group.

Specific examples of the compound represented by General Formula (b0-1-3) are shown below.

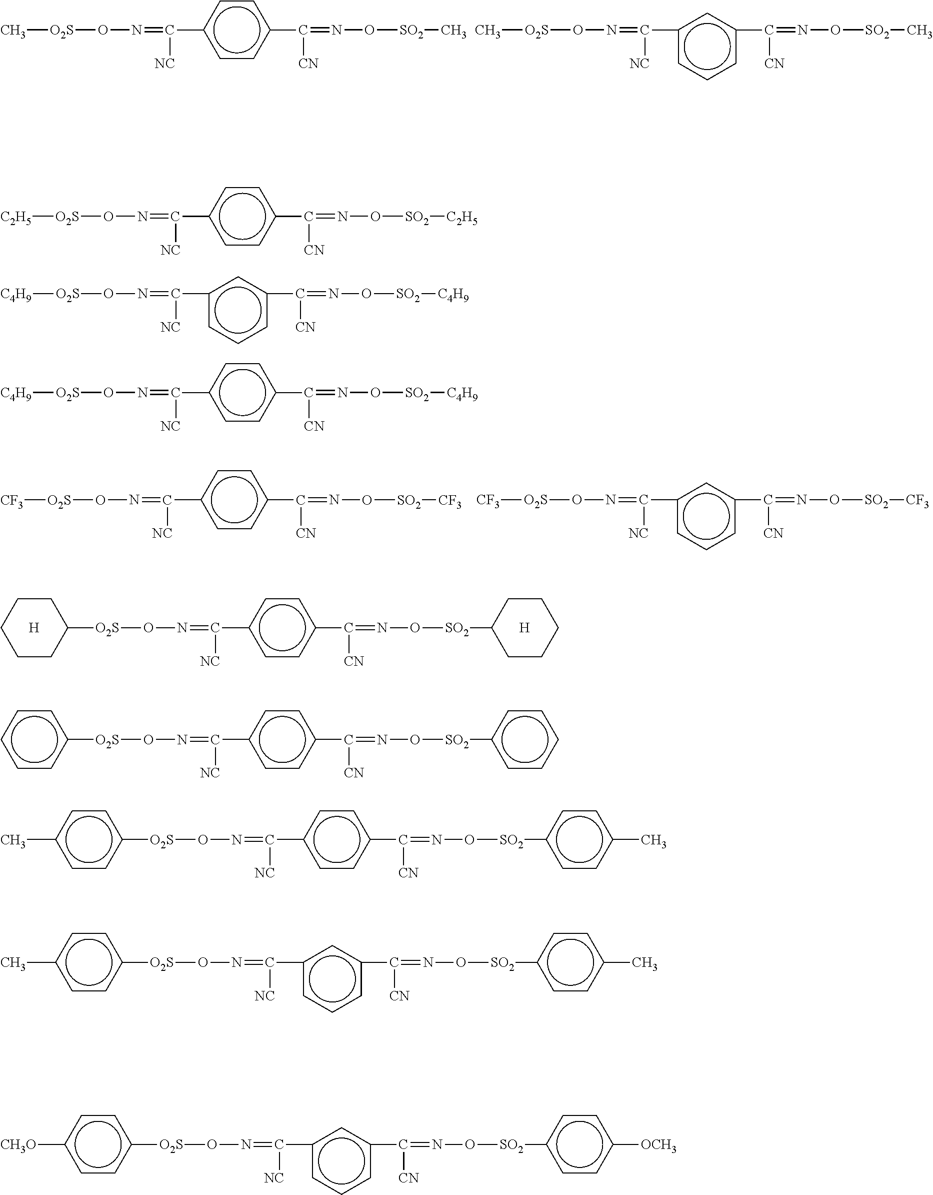

In General Formula (b0-1-4), examples of the aromatic polycyclic hydrocarbon group as Rb¹⁴ include aromatic condensed polycyclic hydrocarbon groups such as a 2-indenyl group, a 1-naphthyl group, a 2-naphthyl group, and a 2-anthryl group, and aromatic non-condensed polycyclic hydrocarbon groups such as a biphenyl group and a terphenyl group. In addition, examples of the group of the substituted derivative thereof include those obtained by substituting the aromatic ring of these groups with a substituent such as a halogen atom such as a chlorine atom, a bromine atom, or an iodine atom, a nitro group, an amino group, a hydroxyl group, an alkyl group, or an alkoxyl group, for examples, a 5-hydroxy-1-naphthyl group and a 4-amino-1-naphthyl group.

In General Formula (b0-1-4), examples of the saturated or unsaturated non-aromatic polycyclic hydrocarbon group as Rb¹⁴ include a polycyclic terpene residue and an adamantyl group, where a polycyclic terpene residue is preferable. In addition, examples of the group of the substituted derivative thereof include those having a suitable substituent such as a halogen atom such as a chlorine atom, a bromine atom, or an iodine atom, a nitro group, an amino group, a hydroxyl group, an oxo group, an alkyl group, or an alkoxyl group. Examples of such as those include a camphor-3-yl group, a camphor-8-yl group, a camphor-10-yl group, and a 3-bromocamphor-10-yl group.

Rb¹⁴ is preferably a naphthyl group or a camphor-10-yl group, and it is suitably a 1-naphthyl group, particularly from the viewpoint that resolution is excellent.

In General Formula (b0-1-4), the inert organic group as Rb²⁴ is an organic group that is inert to coexisting components under the conditions of use and is not particularly limited; however, it is preferably an aromatic group from the viewpoint of sensitivity to excimer lasers, electron beams, or X-rays. Examples of the aromatic group include a phenyl group, a naphthyl group, a furyl group, and a thienyl group. In addition, these aromatic groups may have a halogen atom such as a chlorine atom, a bromine atom, or an iodine atom, or an inert substituent such as an alkyl group, an alkoxyl group, or a nitro group.

Specific examples of the compound represented by General Formula (b0-1-4) include α-(1-naphthylsulfonyloxyimino)-4-methoxybenzyl cyanide, α-(2-naphthylsulfonyloxyimino)-4-methoxybenzyl cyanide, α-(1-naphthylsulfonyloxyimino)benzyl cyanide, α-(2-naphthylsulfonyloxyimino)benzyl cyanide, α-(10-camphorsulfonyloxyimino)-4-methoxybenzyl cyanide, α-(10-camphorsulfonyloxyimino)benzyl cyanide, α-(3-camphorsulfonyloxyimino)-4-methoxybenzyl cyanide, and α-(3-bromo-10-camphorsulfonyloxyimino)-4-methoxybenzyl cyanide.

In General Formula (b0-1-5), examples of the substituted or unsubstituted monovalent saturated hydrocarbon group and the unsaturated hydrocarbon group, as Rb¹⁵, include linear or branched hydrocarbon groups having 1 to 8 carbon atoms, which are saturated or unsaturated, and groups obtained by substituting these groups with a halogen atom, a nitro group, an acetylamino group, a lower alkoxy group, or a monocyclic aryl group, where those having a substituent such as a halogen atom or a lower alkoxy group are preferable. In addition, examples of the substituted or unsubstituted monovalent aromatic group as Rb¹⁵ include monocyclic or dicyclic groups, where those obtained by substituting particularly the benzene ring with a vinyl group, an alkyl group, an alkoxy group, or a halogen atom is preferable.

In General Formula (b0-1-5), examples of the cyclic group having a cyclic imide structure formed by Xb⁵ together with —(O═)C—N—C(═O)— include a succinimide ring, a maleimide ring, a glutarimide ring, a phthalimide ring, and a 1,8-naphthalene dicarboximide ring.

The cyclic group having a cyclic imide structure formed by Xb⁵ together with —(O═)C—N—C(═O)— may have a substituent. Examples of the substituent include a halogen atom, a nitro group, an acetylamino group, an alkoxy group, and a monocyclic aryl group.

Specific examples of the compound represented by General Formula (b0-1-5) include N-methylsulfonyloxysuccinimide, N-isopropylsulfonyloxysuccinimide, N-chloroethylsulfonyloxysuccinimide, N-(p-methoxyphenyl)sulfonyloxysuccinimide, N-(p-vinylphenyl)sulfonyloxysuccinimide, N-naphthylsulfonyloxysuccinimide, N-phenylsulfonyloxysuccinimide, N-(2,4,6-trimethylphenyl)sulfonyloxysuccinimide, N-methylsulfonyloxymaleimide, N-isopropylsulfonyloxymaleimide, N-chloroethylsulfonyloxymaleimide, N-(p-methoxyphenyl)sulfonyloxymaleimide, N-(p-vinylphenyl)sulfonyloxymaleimide, N-naphthylsulfonyloxymaleimide, N-phenylsulfonyloxymaleimide, N-(2,4,6-trimethylphenyl)sulfonyloxymaleimide, N-methylsulfonyloxyphthalimide, N-isopropylsulfonyloxyphthalimide, N-chloroethylsulfonyloxyphthalimide, N-(p-methoxyphenyl)sulfonyloxyphthalimide, N-(p-vinylphenyl)sulfonyloxyphthalimide, N-naphthylsulfonyloxyphthalinide, N-phenylsulfonyloxyphthalimide, N-(2,4,6-trimethylphenyl)sulfonyloxyphthalimide, and compounds described in paragraphs [0089] to [0091] of Japanese Unexamined Patent Application, First Publication No. H10-097075.

In General Formula (b0-1-6), the alkyl group as Rb¹⁶ is preferably a linear, branched, or cyclic alkyl group having 1 to 18 carbon atoms, and examples thereof include a methyl group, an ethyl group, a propyl group, an isopropyl group, an n-butyl group, a sec-butyl group, an isobutyl group, a tert-butyl group, a pentyl group, a hexyl group, a heptyl group, a 2,4,4-trimethylpentyl group, a 2-ethylhexyl group, an octyl group, a nonyl group, a decyl group, an undecyl group, a dodecyl group, a tetradecyl group, a pentadecyl group, a hexadecyl group, a heptadecyl group, an octadecyl group, a cyclopentyl group, a cyclohexyl group, a cyclooctyl group, and a cyclododecyl group.

Among them, the alkyl group as Rb¹⁶ is preferably a linear or branched alkyl group having 1 to 10 carbon atoms, and more preferably a linear or branched alkyl group having 1 to 5 carbon atoms.

The alkyl group as Rb¹⁶ may have a substituent. Examples of the substituent include a halogen atom, a halogenated alkyl group, CN, NO₂, a phenyl group, an alkoxy group, a carboxy group, a carbonyl group, a sulfonyl group, and an amino group.

In General Formula (b0-1-6), examples of the aromatic hydrocarbon group as Rb¹⁶ include a phenyl group, a naphthyl group, a phenanthryl group, an anthracyl group, and a heteroaryl group.

The aromatic hydrocarbon group as Rb¹⁶ may have a substituent. Examples of the substituent include a halogen atom, a halogenated alkyl group, CN, NO₂, a phenyl group, an alkoxy group, a carboxy group, a carbonyl group, a sulfonyl group, and an amino group.

Specific examples of the compound represented by General Formula (b0-1-6) include a compound represented by Chemical Formula (b0-1-61) and the compounds in Examples 25 to 40 and 53 of Published Japanese Translation No. 2002-508774 of the PCT International Publication.

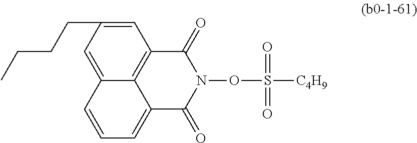

Other specific examples of the component (B0) include compounds described in paragraphs [0056], [0058], [0060], and [0063] of Japanese Patent No. 4110392, and paragraphs [0053], [0054], [0056], [0058], and [0060] to [0062] of Japanese Patent No. 4000469.

Among them, the component (B0) is preferably at least one selected from the group consisting of the compound represented by General Formula (b0-1-2), the compound represented by General Formula (b0-1-3), and the compound represented by General Formula (b0-1-5), and the compound represented by General Formula (b0-1-6), and it is more preferably at least one selected from the group consisting of the compound represented by General Formula (b0-1-2), the compound represented by General Formula (b0-1-3), and the compound represented by General Formula (b0-1-6).

Further, from the viewpoint of achieving both sensitivity and resolution, it is also preferable to use in combination the compound represented by General Formula (b0-1-2) and/or the compound represented by General Formula (b0-1-3), and the compound represented by General Formula (b0-1-6).

Preferred specific examples of the component (B0) are shown below.

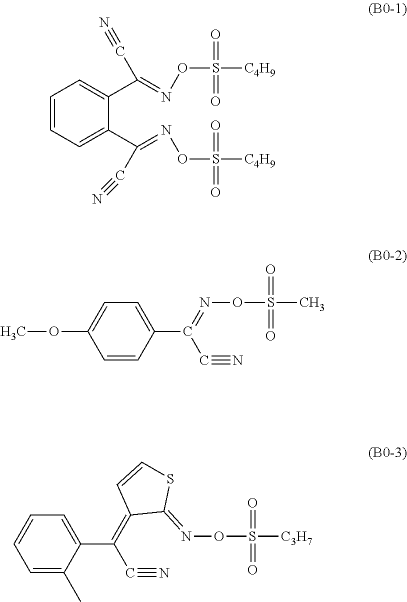

The component (B0) contained in the resist composition according to the present embodiment may be used alone or in a combination of two or more kinds thereof.

The content of the component (B0) in the resist composition according to the present embodiment is preferably in a range of 50 parts by mass or less, more preferably in a range of 0.1 to 40 parts by mass, still more preferably in a range of 0.1 to 30 parts by mass, and particularly preferably in a range of 0.1 to 20 parts by mass, with respect to 100 parts by mass of the component (A).

In a case where the content of the component (B0) is set to be in the above-described range, pattern formation can be sufficiently carried out.

### In Regard to Component (B1)

The resist composition according to the present embodiment may further contain an acid generator (hereinafter, referred to as a “component (B1)”) other than the component (B0).

The component (B1) is not particularly limited, and those which have been proposed so far as an acid generator for a chemical amplification-type resist composition in the related art can be used.

Examples of these acid generators are numerous and include onium salt-based acid generators such as an iodonium salt and a sulfonium salt; oxime sulfonate-based acid generators; diazomethane-based acid generators such as bisalkyl or bisaryl sulfonyl diazomethanes and poly(bis-sulfonyl)diazomethanes; nitrobenzyl sulfonate-based acid generators; and disulfonate-based acid generators.

Examples of the onium salt-based acid generator include a compound represented by General Formula (b-1) (hereinafter, also referred to as a “component (b-1)”), a compound represented by General Formula (b-2) (hereinafter, also referred to as a “component (b-2)”), and a compound represented by General Formula (b-3) (hereinafter, also referred to as a “component (b-3)”).

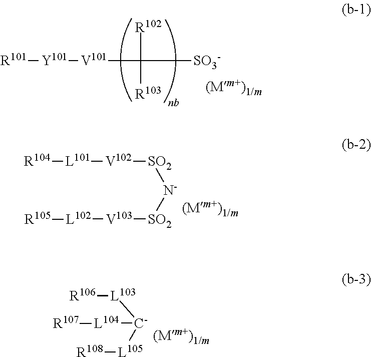

[In the formulae, R¹⁰¹ and R¹⁰⁴ to R¹⁰⁸ each independently represent a cyclic group which may have a substituent, a chain-like alkyl group which may have a substituent, or a chain-like alkenyl group which may have a substituent. R¹⁰⁴ and R¹⁰⁵ may be bonded to each other to form a ring. R¹⁰² and R¹⁰³ each independently represent a hydrogen atom, an alkyl group having 1 to 5 carbon atoms, a fluorine atom, or a fluorinated alkyl group having 1 to 5 carbon atoms. nb represents 0 or 1. Y¹⁰¹ represents a single bond or a divalent linking group containing an oxygen atom. V¹⁰¹ to V¹⁰³ each independently represent a single bond, an alkylene group, or a fluorinated alkylene group. L¹⁰¹ and L¹⁰² each independently represent a single bond or an oxygen atom. L¹⁰³ to L¹⁰⁵ each independently represent a single bond, —CO— or —SO₂—. m represents an integer of 1 or more, and M′^{m+} represents an m-valent onium cation.]

In General Formula (b-1), R¹⁰¹ is preferably a cyclic group which may have a substituent, and more preferably a cyclic hydrocarbon group which may have a substituent. More specifically, it is preferably a group obtained by removing one or more hydrogen atoms from a phenyl group, a naphthyl group, a polycycloalkane; a group obtained by removing one or more hydrogen atoms from camphor; each of lactone-containing cyclic groups represented by General Formulae (a2-r-1) and (a2-r-3) to (a2-r-7); or each of —SO₂—-containing cyclic groups represented by General Formulae (a5-r-1) to (a5-r-4) (any group may have a substituent).

In General Formula (b-1), Y¹⁰¹ is preferably a single bond, a divalent linking group containing an ester bond, or a divalent linking group containing an ether bond.

In General Formula (b-1), V¹⁰¹ is preferably a single bond or a fluorinated alkylene group having 1 to 4 carbon atoms.

In General Formula (b-1), R¹⁰² is preferably a hydrogen atom, a fluorine atom, or a perfluoroalkyl group having 1 to 5 carbon atoms.

In General Formula (b-2), R¹⁰⁴ and R¹⁰⁵ each independently represent a cyclic group which may have a substituent, a chain-like alkyl group which may have a substituent, or a chain-like alkenyl group which may have a substituent, and examples thereof each include the same one as R¹⁰¹ in General Formula (b-1). However, R¹⁰⁴ and R¹⁰⁵ may be bonded to each other to form a ring.

R¹⁰⁴ and R¹⁰⁵ are preferably a chain-like alkyl group which may have a substituent and more preferably a linear or branched alkyl group or a linear or branched fluorinated alkyl group.

In General Formula (b-2), V¹⁰² and V¹⁰³ each independently represent a single bond, an alkylene group, or a fluorinated alkylene group, and examples thereof each include the same ones as V¹⁰¹ in General Formula (b-1).

In General Formula (b-2), L¹⁰¹ and L¹⁰² each independently represent a single bond or an oxygen atom.

In General Formula (b-3), R¹⁰⁶ to R¹⁰⁸ each independently represent a cyclic group which may have a substituent, a chain-like alkyl group which may have a substituent, or a chain-like alkenyl group which may have a substituent, and examples thereof include the same one as R¹⁰¹ in General Formula (b-1).

L¹⁰³ to L¹⁰⁵ each independently represent a single bond, —CO—, or —SO₂—.]

In General Formulae (b-1), (b-2), and (b-3), m represents an integer of 1 or more. M′^{m+} represents an m-valent onium cation and suitable examples thereof include a sulfonium cation and an iodonium cation.

In the resist composition according to the present embodiment, the component (B1) may be used alone or in a combination of two or more kinds thereof.

In a case where the resist composition contains the component (B1), the content of the component (B1) in the resist composition is preferably 50 parts by mass or less, more preferably in a range of 0.1 to 40 parts by mass, still more preferably in a range of 0.1 to 30 parts by mass, and particularly preferably in a range of 0.1 to 20 parts by mass, with respect to 100 parts by mass of the component (A).

In the resist composition according to the present embodiment, the component (B) may be used alone or in a combination of two or more kinds thereof.

The content of the component (B) in the resist composition according to the present embodiment is preferably less than 50 parts by mass, more preferably in a range of 0.1 to 40 parts by mass, and still more preferably in a range of 0.3 to 25 parts by mass, with respect to 100 parts by mass of the component (A).

In a case where the content of the component (B) is set to be in the preferred range described above, pattern formation can be sufficiently carried out. Further, in a case where each component of the resist composition is dissolved in an organic solvent, the above range is preferable since a homogeneous solution is easily obtained and the storage stability of the resist composition is improved.

### <Component (C)>

The component (C) is at least one crosslinking agent (C) selected from the group consisting of a melamine-based crosslinking agent, a urea-based crosslinking agent, an alkylene urea-based crosslinking agent, a glycoluril-based crosslinking agent, and an epoxy-based crosslinking agent.

Examples of the melamine-based crosslinking agent include a compound obtained by reacting melamine with formaldehyde to substitute a hydrogen atom of an amino group with a hydroxymethyl group; and a compound obtained by reacting melamine, formaldehyde, and a lower alcohol to substitute a hydrogen atom of an amino group with a lower alkoxymethyl group. Specific examples thereof include hexamethoxymethyl melamine, hexaethoxymethyl melamine, hexapropoxymethyl melamine, and hexabutoxybutyl melamine, among which hexamethoxymethyl melamine is preferable.

Examples of the urea-based crosslinking agent include a compound obtained by reacting urea with formaldehyde to substitute a hydrogen atom of an amino group with a hydroxymethyl group; and a compound obtained by reacting urea, formaldehyde, and a lower alcohol to substitute a hydrogen atom of an amino group with a lower alkoxymethyl group. Specific examples thereof include bismethoxymethyl urea, bisethoxymethyl urea, bispropoxymethyl urea, and bisbutoxymethyl urea, among which bismethoxymethyl urea is preferable.

Examples of the alkylene urea-based crosslinking agent include a compound represented by General Formula (CA-1).

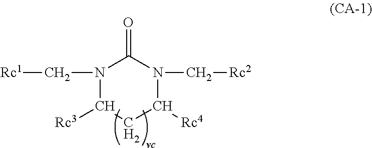

[In General Formula (CA-1), Rc¹ and Rc² each independently represent a hydroxyl group or a lower alkoxy group, Rc³ and Rc⁴ each independently represent a hydrogen atom, a hydroxyl group, or a lower alkoxy group, and vc represents an integer in a range of 0 to 2.]

In a case of representing a lower alkoxy group, Rc¹ and Rc² are preferably an alkoxy group having 1 to 4 carbon atoms and may be linear or branched. Rc¹ and Rc² may be the same or different from each other. They are more preferably the same.

In a case of representing a lower alkoxy group, Rc³ and Rc⁴ are preferably an alkoxy group having 1 to 4 carbon atoms and may be linear or branched. Rc³ and Rc⁴ may be the same or different from each other. They are more preferably the same.

vc represents an integer in a range of 0 to 2 and is preferably 0 or 1.

In particular, the alkylene urea-based crosslinking agent is preferably a compound in which vc is 0 (an ethylene urea-based crosslinking agent) and/or a compound in which vc is 1 (a propylene urea-based crosslinking agent).

The compound represented by General Formula (CA-1) can be obtained by subjecting an alkylene urea to a condensation reaction with formalin or by subjecting the product of this reaction to a reaction with a lower alcohol.

Specific examples of the alkylene urea-based crosslinking agent include ethylene urea-based crosslinking agents such as mono- and/or dihydroxymethylated ethylene urea, mono- and/or dimethoxymethylated ethylene urea, mono- and/or diethoxymethylated ethylene urea, mono- and/or dipropoxyethylated ethylene urea, and mono- and/or dibutoxymethylated ethylene urea; propylene urea-based crosslinking agents such as mono- and/or dihydroxymethylated propylene urea, mono- and/or dimethoxymethylated propylene urea, mono- and/or diethoxymethylated propylene urea, mono- and/or dipropoxymethylated propylene urea, and mono- and/or dibutoxymethylated propylene urea; 1,3-di(methoxymethyl) 4,5-dihydroxy-2-imidazolidinone; and 1,3-di(methoxymethyl)-4,5-dimethoxy-2-imidazolidinone.

Examples of the glycoluril-based crosslinking agent include a glycoluril derivative having a substitution with one or both of a hydroxyalkyl group and an alkoxyalkyl group having 1 to 4 carbon atoms at the N-position. Such a glycoluril derivative can be obtained by subjecting glycoluril to a condensation reaction with formalin or by subjecting the product of this reaction to a reaction with a lower alcohol.

Specific examples of the glycoluril-based crosslinking agents include mono-, di-, tri-, and/or tetra-hydroxymethylated glycoluril; mono-, di-, tri-, tri-, and/or tetra-methoxymethylated glycoluril; mono-, di-, tri-, and/or tetra-ethoxymethylated glycoluril; mono-, di-, tri-, and/or tetra-propoxymethylated glycoluril; and mono-, di-, tri-, and/or tetra-butoxymethylated glycoluril.

The epoxy-based crosslinking agent is not particularly limited as long as it has an epoxy group, and any epoxy-based crosslinking agent can be selected and used. Among the above, the one having two or more epoxy groups is preferable. In a case where two or more epoxy groups are contained, crosslinking reactivity is improved.

The number of epoxy groups is preferably 2 or more, more preferably 2 to 4, and most preferably 2.

Suitable epoxy-based crosslinking agents are shown below.

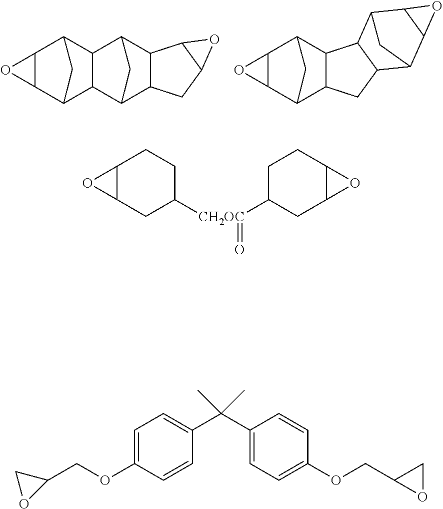

Among the above, the component (C) is preferably a crosslinking agent having a —NCH₂—OCH₃ group, more preferably a crosslinking agent selected from the group consisting of a compound represented by General Formula (c1-1) or (c1-2) and a mono-, di-, tri- and/or tetra-methoxymethylated glycoluril, and still more preferably a crosslinking agent selected from the group consisting of a compound represented by General Formula (c1-1) or (c1-2) and having a melamine skeleton, and a mono-, di-, tri- and/or tetra-methoxymethylated glycoluril.

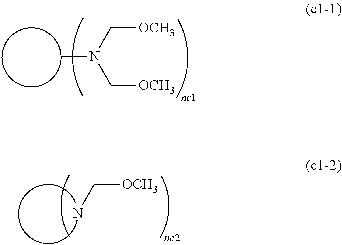

[In the formula, nc1 and nc2 each independently represent an integer in a range of 1 to 3.]

One kind of the component (C) may be used alone, or two or more kinds thereof may be used in combination.

In the resist composition according to the present embodiment, the content of the component (C) is preferably in a range of 1 to 50 parts by mass, more preferably in a range of 3 to 40 parts by mass, still more preferably in a range of 3 to 30 parts by mass, and most preferably in a range of 5 to 25 parts by mass, with respect to 100 parts by mass of the component (A).

In a case where the content of the component (C) is equal to or larger than the lower limit value thereof, the crosslinking proceeds sufficiently, and thus resolution performance and lithography characteristics are further improved. Further, a good resist pattern with less swelling can be obtained. In addition, in a case where the content thereof is equal to or smaller than this upper limit value, the storage stability of the resist composition is good, and the temporal deterioration of the sensitivity is easily suppressed.

### <(Z) Component>

The component (Z) is not particularly limited as long as it is a polyether compound, and examples thereof include compounds having a partial structure represented by General Formula (z-1).

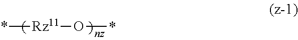

[In the formula, Rz¹¹ represents an alkylene group which may have a substituent. nz represents an integer of 1 or more.]

In General Formula (z-1), Rz¹¹ represents an alkylene group which may have a substituent. Although the number of carbon atoms in the alkylene group is not particularly limited, it is preferably in a range of 1 to 15, more preferably in a range of 2 to 8, and still more preferably in a range of 2 to 4. Although the substituent is not particularly limited, it is preferably an alkyl group (preferably having 1 to 10 carbon atoms).

In General Formula (z-1), * represents a bonding site.

The mass average molecular weight (Mw) of the compound represented by General Formula (z-1) (in terms of the polystyrene equivalent value determined by gel permeation chromatography (GPC)) is preferably in a range of 200 to 25,000, more preferably in a range of Mw of 250 to 24,000, and still more preferably in a range of Mw of 300 to 23,000.

The component (Z) is preferably a compound represented by General Formula (z-1-1).

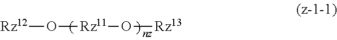

[In the formula, Rz¹¹ represents an alkylene group which may have a substituent. Rz¹² and Rz¹³ each independently represent a hydrogen atom or an alkyl group. nz represents an integer of 1 or more.]

The definition, specific examples, and preferred aspect of Rz¹¹ in General Formula (z-1-1) are the same as those of Rz¹¹ in General Formula (1).

In General Formula (z-1-1), Rz¹² and Rz¹³ each independently represent a hydrogen atom or an alkyl group. Although the number of carbon atoms in the alkyl group is not particularly limited, it is preferably in a range of 1 to 15. Among the above, Rz¹² and Rz¹³ re preferably a hydrogen atom.

The mass average molecular weight (Mw) of the compound represented by General Formula (z-1-1) (in terms of the polystyrene equivalent value determined by gel permeation chromatography (GPC)) is preferably in a range of 200 to 25,000, more preferably in a range of Mw of 250 to 24,000, and still more preferably in a range of Mw of 300 to 23,000.

Among the above, the component (Z) is more preferably at least one selected from the group consisting of a compound represented by General Formula (z-1-11), a compound represented by General Formula (z-1-12), and a compound represented by General Formula (z-1-13).

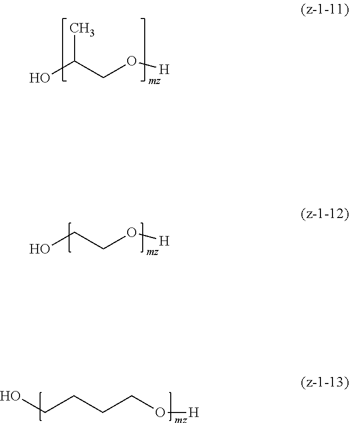

The mass average molecular weight (Mw) of (Z) (in terms of the polystyrene equivalent value determined by gel permeation chromatography (GPC)) is preferably in a range of 200 to 25,000, more preferably in a range of 250 to 24,000, and still more preferably in a range of 300 to 23,000.

In a case where the mass average molecular weight (Mw) of (Z) is equal to or larger than the lower limit value of the above-described preferred range, it is easy to form a pattern having good wet etching resistance. On the other hand, in a case where the mass average molecular weight (Mw) of (Z) is equal to or smaller than the upper limit value of the above-described preferred range, the solubility of the resist film in a developing solution tends to be good, and a pattern having good resolution is easily formed.

The component (BZ) contained in the resist composition according to the present embodiment may be used alone or in a combination of two or more kinds thereof.

In the resist composition according to the present embodiment, the content of component (Z) is less than 50 parts by mass, preferably 40 parts by mass or less, more preferably 35 parts by mass or less, still more preferably 30 parts by mass or less, and even still more preferably less than 20 parts by mass, with respect to 100 parts by mass of component (A1).

The lower limit value of the content of component (Z) is not particularly limited; however, it is preferably 0.1 parts by mass or more, more preferably 0.2 parts by mass or more, and still more preferably 0.5 parts by mass or more, with respect to 100 parts by mass of component (A1).

In a case where the content of the component (Z) is less than 50 parts by mass, a pattern having good resolution and good wet etching resistance can be formed.

In a case where the content of the component (Z) is equal to or smaller than the upper limit value of the above-described preferred range, it is easy to form a pattern having better resolution.

In a case where the content of the component (Z) is equal to or larger than the lower limit value of the above-described preferred range, it is easy to form a pattern having better wet etching resistance.

### <Optional Component>

### <<Component (D)>>

The resist composition in the present embodiment may further contain an acid diffusion controlling agent component (hereinafter, referred to as a “component (D)”), in addition to the component (A), the component (B), the component (C), and the component (Z). The component (D) acts as a quencher (an acid diffusion controlling agent) which traps the acid generated upon exposure in the resist composition.

Examples of the component (D) include a nitrogen-containing organic compound (D1) (hereinafter, referred to as a “component (D1)”) and a photodecomposable base (D2) (hereinafter, referred to as a “component (D2)”) which does not correspond to the component (D1) and has an acid diffusion controllability that is lost by the decomposition upon exposure.

In a case where a resist composition containing the component (D) is obtained, the contrast between the exposed portions and unexposed portions of the resist film can be further improved at the time of forming a resist pattern.

### In Regard to Component (D1)

The component (D1) is a base component and is a nitrogen-containing organic compound component that acts as an acid diffusion controlling agent in the resist composition.

The component (D1) is not particularly limited as long as it acts as an acid diffusion controlling agent, and examples thereof include aliphatic amines and an aromatic amines.

Among the aliphatic amines, a secondary aliphatic amine or a tertiary aliphatic amines is preferable.

The aliphatic amine is preferably an amine having one or more aliphatic groups, where the aliphatic group has 1 to 12 carbon atoms.

Examples of these aliphatic amines include an amine in which at least one hydrogen atom of ammonia (NH₃) has been substituted with an alkyl group or hydroxyalkyl group having 12 or less carbon atoms (alkyl amines or alkyl alcohol amines) and a cyclic amine.

Specific examples of the alkyl amine and the alkyl alcohol amine include monoalkyl amines such as n-hexyl amine, n-heptyl amine, n-octyl amine, n-nonyl amine, and n-decyl amine; dialkyl amines such as diethyl amine, di-n-propyl amine, di-n-heptyl amine, di-n-octyl amine, and dicyclohexyl amine; trialkyl amines such as trimethyl amine, triethyl amine, tri-n-propyl amine, tri-n-butyl amine, tri-n-pentyl amine, tri-n-hexyl amine, tri-n-heptyl amine, tri-n-octyl amine, tri-n-nonyl amine, tri-n-decyl amine, and tri-n-dodecyl amine; and alkyl alcohol amines such as diethanol amine, triethanol amine, diisopropanol amine, triisopropanol amine, di-n-octanol amine, and tri-n-octanol amine. Among these, trialkyl amines of 5 to 10 carbon atoms are preferable, and tri-n-pentyl amine and tri-n-octyl amine are particularly preferable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples thereof include 1, 5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine and triethanol amine triacetate, and triethanol amine triacetate is preferable.

Examples of aromatic amines include 4-dimethylaminopyridine, pyrrole, indole, pyrazole, imidazole, and derivatives thereof, tribenzylamine, an aniline compound, and N-tert-butoxycarbonylpyrrolidine.

The component (D1) may be used alone or in a combination of two or more kinds thereof.

Among them, the component (D1) is preferably an aromatic amine and more preferably an aniline compound. Examples of aniline compound include 2,6-diisopropylaniline, N,N-dimethylaniline, N,N-dibutylaniline, and N,N-dihexylaniline.

### In Regard to Component (D2)

The component (D2) is not particularly limited as long as it is decomposed upon exposure and loses the acid diffusion controllability. The component (D2) is preferably one or more compounds selected from the group consisting of a compound represented by General Formula (d2-1) (hereinafter, referred to as a “component (d2-1)”) and a compound represented by General Formula (d2-2) (hereinafter, referred to as a “component (d2-2)”).

At exposed portions of the resist film, the components (d2-1) and (d2-2) are decomposed and then lose the acid diffusion controllability (basicity), and thus they cannot act as a quencher, whereas they act as a quencher at unexposed portions of the resist film.

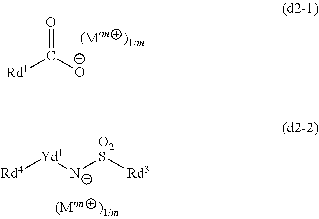

[In the formulae, Rd¹, Rd³, and Rd⁴ each independently represent a cyclic group which may have a substituent, a chain-like alkyl group which may have a substituent, or a chain-like alkenyl group which may have a substituent. Yd¹ represents a single bond or a divalent linking group. m represents an integer of 1 or more, and each M′^{m+} independently represents an m-valent onium cation.]

In General Formula (d2-1), Rd¹ is preferably an aromatic hydrocarbon group which may have a substituent, an aliphatic cyclic group which may have a substituent, or a chain-like alkyl group which may have a substituent.

In General Formula (d2-2), Rd³ is preferably a cyclic group containing a fluorine atom, a chain-like alkyl group, or a chain-like alkenyl group.

In General Formula (d2-2), Rd⁴ is preferably an alkyl group, an alkoxy group, an alkenyl group, or a cyclic group, which may have a substituent.

In General Formula (d2-2), Yd¹ is preferably a carbonyl group, an ester bond, an amide bond, an alkylene group, or a combination thereof.

In General Formulae (d2-1) and (d2-2), m is an integer of 1 or more. M′^{m+} is an m-valent onium cation, and suitable examples thereof include a sulfonium cation and an iodonium cation.

As the component (D2), only one of the above-described components (d2-1) and (d2-2) or a combination of two or more kinds thereof may be used.

In a case where the resist composition contains the component (D2), the content of the component (D2) in the resist composition is preferably less than 0.5 to 35 parts by mass, more preferably in a range of 1 to 25 parts by mass, still more preferably in a range of 2 to 20 parts by mass, and particularly preferably in a range of 3 to 15 parts by mass, with respect to 100 parts by mass of the component (A).

In a case where the content of the component (D2) is equal to or larger than the preferred lower limit value, excellent lithography characteristics and an excellent resist pattern shape are easily obtained. On the other hand, in a case where it is equal to or smaller than the upper limit value thereof, balance with other components can be obtained, and thus various lithography characteristics are improved.

### Method for Producing Component (D2):

The method for producing the components (d2-1) described above is not particularly limited, and the component (d1-1) can be produced by a conventionally known method.

Further, the method for producing the component (d2-2) is not particularly limited, and the component (d2-2) can be produced in the same manner as disclosed in United States Patent Application, Publication No. 2012-0149916.

<<Component (E): At Least One Compound Selected from Group Consisting of Organic Carboxylic Acid, Phosphorus Oxo Acid, and Derivatives Thereof>>

For the intended purpose of preventing any deterioration in sensitivity and improving the resist pattern shape and the post-exposure temporal stability, the resist composition according to the present embodiment may contain, as an optional component, at least one compound (E) (hereinafter referred to as a component (E)) selected from the group consisting of an organic carboxylic acid, and a phosphorus oxo acid and a derivative thereof.

Examples of the suitable organic carboxylic acid include acetic acid, malonic acid, citric acid, malic acid, succinic acid, benzoic acid, and salicylic acid.

Examples of the phosphorus oxo acid include phosphoric acid, phosphonic acid, and phosphinic acid. Among these, phosphonic acid is particularly preferable.

Examples of the phosphorus oxo acid derivative include an ester obtained by substituting a hydrogen atom in the above-described oxo acid with a hydrocarbon group. Examples of the hydrocarbon group include an alkyl group having 1 to 5 carbon atoms and an aryl group having 6 to 15 carbon atoms.

Examples of the phosphoric acid derivative include a phosphoric acid ester such as di-n-butyl phosphate or diphenyl phosphate.

Examples of the phosphonic acid derivative include phosphonic acid esters such as dimethyl phosphonate, di-n-butyl phosphonate, phenylphosphonic acid, diphenyl phosphonate, and dibenzyl phosphonate.

Examples of the phosphinic acid derivative include phosphinic acid esters and phenylphosphinic acid.

In the resist composition according to the present embodiment, the component (E) may be used alone or in a combination of two or more kinds thereof.

In a case where the resist composition contains the component (E), the content of the component (E) is generally used in a range of 0.01 to 5 parts by mass with respect to 100 parts by mass of the component (A).

### <<Component (S): Organic Solvent Component>>

The resist composition according to the present embodiment may be produced by dissolving the resist materials in an organic solvent component (hereinafter, referred to as a “component (S)”).

The component (S) may be any organic solvent which can dissolve each of the components to be used to obtain a homogeneous solution, and any organic solvent can be appropriately selected from solvents for a chemical amplification-type resist composition, which are known in the related art, and then used.

Examples of the component (S) include lactones such as γ-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; derivatives of polyhydric alcohols such as compounds having an ether bond, such as monoalkyl ethers (such as monomethyl ether, monoethyl ether, monopropyl ether, and monobutyl ether) of the above-described polyhydric alcohols or the above-described compounds having an ester bond, and monophenyl ethers [among these, propylene glycol monomethyl ether acetate (PGMEA) and propylene glycol monomethyl ether (PGME) are preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethyl benzyl ether, cresyl methyl ether, diphenyl ether, dibenzyl ether, phenetole, butyl phenyl ether, ethyl benzene, diethyl benzene, pentyl benzene, isopropyl benzene, toluene, xylene, cymene and mesitylene; and dimethylsulfoxide (DMSO).

In the resist composition according to the present embodiment, the component (S) may be used alone or as a mixed solvent of two or more kinds thereof.

Among these, PGMEA, PGME, γ-butyrolactone, EL, or cyclohexanone is preferable.

Further, a mixed solvent obtained by mixing PGMEA with a polar solvent is also preferable. The blending ratio (mass ratio) of the mixed solvent can be appropriately determined, taking into consideration the compatibility of the PGMEA with the polar solvent; however, it is preferably in a range of 1:9 to 9:1 and more preferably in a range of 2:8 to 8:2.

More specifically, in a case where EL or cyclohexanone is blended as the polar solvent, the PGMEA:EL or cyclohexanone mass ratio is preferably in a range of 1:9 to 9:1 and more preferably in a range of 2:8 to 8:2. Alternatively, in a case where PGME is blended as the polar solvent, the PGMEA:PGME mass ratio is preferably in a range of 1:9 to 9:1, more preferably in a range of 2:8 to 8:2, and still more preferably in a range of 3:7 to 7:3. Furthermore, a mixed solvent of PGMEA, PGME, and cyclohexanone is also preferable.

Further, the component (S) is also preferably a mixed solvent of at least one selected from PGMEA and EL and γ-butyrolactone. In this case, as the mixing ratio, the mass ratio of the former to the latter is preferably in a range of 70:30 to 95:5.

The amount of the component (S) to be used is not particularly limited and is appropriately set, depending on a thickness of a film to be coated, to a concentration at which the component (S) can be applied onto a substrate or the like. Generally, the component (S) is used such that the solid content concentration of the resist composition is in a range of 0.1% to 50% by mass and preferably in a range of 10% to 50% by mass.

As desired, other miscible additives can also be added to the resist composition according to the present embodiment. The resist composition may appropriately contain miscible additives such as an additive resin for improving the performance of the resist film, an ionic or non-ionic fluorine-based and/or silicon-based surfactant, a dissolution inhibitor, a plasticizer, a stabilizer, a colorant, a halation prevention agent, and a dye.

After dissolving the resist material in the component (S), the resist composition according to the present embodiment may be subjected to the removal of impurities and the like by using a porous polyimide membrane, a porous polyamide-imide membrane, or the like. For example, the resist composition may be filtered using a filter made of a porous polyimide membrane, a filter made of a porous polyamide-imide membrane, or a filter made of a porous polyimide membrane and a porous polyamide-imide membrane. Examples of the porous polyimide membrane and the porous polyamide-imide membrane include those described in Japanese Unexamined Patent Application, First Publication No. 2016-155121.

The resist composition according to the present embodiment contains a polymeric compound (A1) having a constitutional unit (a10) represented by General Formula (a10-1); an acid generator (B); at least one crosslinking agent (C) selected from the group consisting of a melamine-based crosslinking agent, a urea-based crosslinking agent, an alkylene urea-based crosslinking agent, a glycoluril-based crosslinking agent, and an epoxy-based crosslinking agent; and a polyether compound (Z).

As a result of studies by the inventors of the present invention, it was found that in a case of using a resist composition that employs an alkali-soluble polyhydroxystyrene-based resin as a base material component to form a thick resist film of the order of microns, forming a resist pattern, and carrying out etching, wet etching resistance may be insufficient. This is conceived to be because the resist film formed using the resist composition has insufficient adhesiveness to the substrate interface.

In the resist composition according to the present embodiment described above, it is presumed that the component (Z) exhibits an effect as a plasticizer in the resist film and increases the contact area between the resist film and the substrate interface. Therefore, it is presumed that the component (A1) and the polar groups present on the substrate surface are easily bonded, which contributes to the improvement of the substrate adhesiveness, thereby improving wet etching resistance while maintaining good resolution.

### (Method for Forming Resist Pattern)

A second aspect according to the present invention is a method for forming a resist pattern, including a step (i) of forming a resist film on a support using the resist composition according to the first aspect described above; a step (ii) of exposing the resist film to light; and a step (iii) of developing the exposed resist film to form a resist pattern.

Examples of one embodiment of such a method for forming a resist pattern include a method for forming a resist pattern carried out as described below.

### Step (i):

First, the resist composition of the above-described embodiment is applied onto a support with a spinner or the like, and a baking (post-apply baking (PAB)) treatment is carried out, for example, at a temperature condition in a range of 80° C. to 160° C. for 40 to 200 seconds, preferably for 60 to 150 seconds to form a resist film.

### Step (ii):

Next, using a light exposure apparatus, for example, a KrF exposure apparatus or the like, the resist film is subjected to selective light exposure by light exposure through a mask (a mask pattern) having a predetermined pattern formed thereon, and then a baking treatment (post-exposure baking (PEB)) is carried out, for example, under a temperature condition of 80° C. to 150° C. for 40 to 150 seconds and preferably 60 to 120 seconds.

Step (iii):

Next, the resist film is subjected to a developing treatment. The developing treatment is carried out using an alkali developing solution in a case of an alkali developing process, and a developing solution containing an organic solvent (organic developing solution) in a case of a solvent developing process.

After the developing treatment, it is preferable to carry out a rinse treatment. As the rinse treatment, water rinsing using pure water is preferable in a case of an alkali developing process, and rinsing using a rinse liquid containing an organic solvent is preferable in a case of a solvent developing process.

In a case of a solvent developing process, after the developing treatment or the rinse treatment, the developing solution or the rinse liquid remaining on the pattern may be removed by a treatment using a supercritical fluid.

After the developing treatment or the rinse treatment, drying is conducted. As desired, a baking treatment (post-baking) may be carried out following the developing treatment. The baking treatment (post-baking) here is carried out, for example, at a temperature of 80° C. or higher and preferably at a temperature condition of 90° C. to 120° C. for 10 to 120 seconds and preferably 300 to 90 seconds.

In this manner, a resist pattern can be formed.

The support is not specifically limited and a conventionally known support in the related art can be used. For example, substrates for electronic components, and such substrates having a predetermined wiring pattern formed thereon can be used. Specific examples thereof include a silicon wafer, a substrate made of a metal such as copper, chromium, iron, or aluminum; and a glass substrate. Suitable examples of the material for a wiring pattern include copper, aluminum, nickel, and gold.

Further, the support may be such a substrate as described above, on which a film of an inorganic and/or organic film is provided. Examples of the inorganic film include an inorganic antireflection film (an inorganic BARC). Examples of the organic film include an organic antireflection film (organic BARC) and an organic film such as a lower-layer organic film used in a multilayer resist method.

Here, the multilayer resist method is a method in which at least one layer of an organic film (lower-layer organic film) and at least one layer of a resist film (upper-layer resist film) are provided on a substrate, and a resist pattern formed on the upper-layer resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is classified into a method in which a double-layer structure consisting of an upper-layer resist film and a lower-layer organic film is formed (double-layer resist method), and a method in which a multilayer structure having three or more layers consisting of an upper-layer resist film, a lower-layer organic film and one or more intermediate layers (thin metal film or the like) provided between the upper-layer resist film and the lower-layer organic film (triple-layer resist method).

The method for forming a resist pattern according to the embodiment is a method useful at the time of being carried out by forming a thick resist film. Even in a case where the film thickness of the resist film formed in the step (i) is, for example, 1 to 10 μm, a resist pattern can be stably formed in a good shape.

The wavelength to be used for exposure is not particularly limited and the exposure can be carried out using an ultraviolet ray such as a g-line or an i-line, ArF excimer laser light, KrF excimer laser light, F₂ excimer laser light, an extreme ultraviolet ray (EUV), a vacuum ultraviolet ray (VUV), an electron beam (EB), or radiation such as an X-ray or a soft X-ray.

The resist composition according to the first aspect described above is highly useful for ultraviolet rays such as a g-line and an i-line, KrF excimer laser light, ArF excimer laser light, EB, or EUV, more highly useful for ultraviolet rays such as a g-line and an i-line, KrF excimer laser light, and ArF excimer laser light, and particularly useful for ultraviolet rays such as a g-line and an i-line, and KrF excimer laser light. The method for forming a resist pattern according to the second aspect is a particularly suitable method in a case where the resist film is irradiated with an ultraviolet ray such as a g-line or an i-line, or KrF excimer laser light in the step (ii).

The exposure method for a resist film may be a general exposure (dry exposure) carried out in air or an inert gas such as nitrogen, or liquid immersion lithography.

The liquid immersion lithography is an exposure method in which the region between the resist film and the lens at the lowermost position of the exposure apparatus is pre-filled with a solvent (liquid immersion medium) that has a larger refractive index than the refractive index of air, and the exposure (liquid immersion exposure) is carried out in this state.

The liquid immersion medium is preferably a solvent that exhibits a refractive index larger than the refractive index of air but smaller than the refractive index of the resist film to be exposed. The refractive index of the solvent is not particularly limited as long as it satisfies the above-described requirements.

Examples of the solvent which exhibits a refractive index that is larger than the refractive index of air but smaller than the refractive index of the resist film include water, fluorine-based inert liquids, silicon-based solvents, and hydrocarbon-based solvents.

As the liquid immersion medium, water is preferable in terms of cost, safety, environment, and versatility.

Examples of the alkali developing solution used for a developing treatment in an alkali developing process include a 0.1% to 10% by mass aqueous solution of tetramethylammonium hydroxide (TMAH).

As the organic solvent contained in the organic developing solution, which is used for a developing treatment in a solvent developing process, any organic solvent capable of dissolving the component (A) (the component (A) prior to exposure) may be appropriately selected from the conventionally known organic solvents. Specific examples of the organic solvent include polar solvents such as a ketone-based solvent, an ester-based solvent, an alcohol-based solvent, a nitrile-based solvent, an amide-based solvent, and an ether-based solvent, and hydrocarbon-based solvents.

The ketone-based solvent is an organic solvent containing C—C(═O)—C in the structure thereof. The ester-based solvent is an organic solvent containing C—C(═O)—O—C in the structure thereof. The alcohol-based solvent is an organic solvent containing an alcoholic hydroxyl group in the structure thereof. The “alcoholic hydroxyl group” indicates a hydroxyl group bonded to a carbon atom of an aliphatic hydrocarbon group. The nitrile-based solvent is an organic solvent containing a nitrile group in the structure thereof. The amide-based solvent is an organic solvent containing an amide group in the structure thereof. The ether-based solvent is an organic solvent containing C—O—C in the structure thereof.

Some organic solvents have a plurality of the functional groups which characterize the above-described solvents in the structure thereof. In such a case, the organic solvent can be classified as any type of solvent having a functional group. For example, diethylene glycol monomethyl ether can be classified as an alcohol-based solvent or an ether-based solvent.

The hydrocarbon-based solvent consists of a hydrocarbon which may be halogenated, and it is a hydrocarbon-based solvent that does not have any substituent other than the halogen atom. Examples of the halogen atom include a fluorine atom, a chlorine atom, a bromine atom, and an iodine atom, and a fluorine atom is preferable.

Among the above, the organic solvent contained in the organic developing solution is preferably a polar solvent and more preferably a ketone-based solvent, an ester-based solvent, or a nitrile-based solvent.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methyl cyclohexanone, phenyl acetone, methyl ethyl ketone, methyl isobutyl ketone, acetyl acetone, acetonyl acetone, ionone, diacetonyl alcohol, acetylcarbinol, acetophenone, methyl naphthyl ketone, isophorone, propylene carbonate, y-butyrolactone and methylamyl ketone (2-heptanone). Among these examples, the ketone-based solvent is preferably methylamyl ketone (2-heptanone).

Examples of the ester-based solvent include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these, the ester-based solvent is preferably butyl acetate.

Examples of the nitrile-based solvent include acetonitrile, propionitrile, valeronitrile, and butyronitrile.

As desired, the organic developing solution may have a conventionally known additive blended. Examples of the additive include surfactants. The surfactant is not particularly limited, and for example, an ionic or non-ionic fluorine-based and/or a silicon-based surfactant can be used. The surfactant is preferably a non-ionic surfactant and more preferably a non-ionic fluorine-based surfactant or a non-ionic silicon-based surfactant.

In a case where a surfactant is blended, the blending amount thereof is typically in a range of 0.001% to 5% by mass, preferably in a range of 0.005% to 2% by mass, and more preferably in a range of 0.01% to 0.5% by mass with respect to the total amount of the organic developing solution.

The developing treatment can be carried out by a conventionally known developing method. Examples thereof include a method in which the support is immersed in the developing solution for a predetermined period (a dip method), a method in which the developing solution is cast upon the surface of the support by surface tension and maintained for a predetermined period (a puddle method), a method in which the developing solution is sprayed onto the surface of the support (spray method), and a method in which a developing solution is continuously ejected from a developing solution ejecting nozzle and applied onto a support which is scanned at a constant rate while being rotated at a constant rate (dynamic dispense method).

As the organic solvent contained in the rinse liquid used in the rinse treatment after the developing treatment in a case of a solvent developing process, an organic solvent hardly dissolving the resist pattern can be appropriately selected and used, among the organic solvents mentioned as organic solvents that are used for the organic developing solution. In general, at least one solvent selected from a hydrocarbon-based solvent, a ketone-based solvent, an ester-based solvent, an alcohol-based solvent, an amide-based solvent, and an ether-based solvent is used. Among these, at least one selected from a hydrocarbon-based solvent, a ketone-based solvent, an ester-based solvent, an alcohol-based solvent, and an amide-based solvent is preferable, at least one selected from an alcohol-based solvent and an ester-based solvent is more preferable, and an alcohol-based solvent is particularly preferable.

The alcohol-based solvent used for the rinse liquid is preferably a monohydric alcohol of 6 to 8 carbon atoms, and the monohydric alcohol may be linear, branched, or cyclic. Specific examples thereof include 1-hexanol, 1-heptanol, 1-octanol, 2-hexanol, 2-heptanol, 2-octanol, 3-hexanol, 3-heptanol, 3-octanol, 4-octanol, and benzyl alcohol. Among these, 1-hexanol, 2-heptanol, and 2-hexanol are preferable, and 1-hexanol and 2-hexanol are more preferable.

As the organic solvent, one kind of solvent may be used alone, or two or more kinds of solvents may be used in combination. Further, an organic solvent other than the above-described examples or water may be mixed thereto. However, in consideration of the development characteristics, the blending amount of water in the rinse liquid is preferably 30% by mass or less, more preferably 10% by mass or less, still more preferably 5% by mass or less, and particularly preferably 3% by mass or less with respect to the total amount of the rinse liquid.

A conventionally known additive can be blended with the rinse liquid as necessary. Examples of the additive include surfactants. Examples of the surfactant include the same ones as those described above, the surfactant is preferably a non-ionic surfactant and more preferably a non-ionic fluorine-based surfactant or a non-ionic silicon-based surfactant.

In a case where a surfactant is blended, the blending amount thereof is typically in a range of 0.001% to 5% by mass, preferably in a range of 0.005% to 2% by mass, and more preferably in a range of 0.01% to 0.5% by mass with respect to the total amount of the rinse liquid.

The rinse treatment using a rinse liquid (washing treatment) can be carried out by a conventionally known rinse method. Examples of the rinse treatment method include a method in which the rinse liquid is continuously ejected and applied onto the support while rotating it at a constant rate (rotational coating method), a method in which the support is immersed in the rinse liquid for a predetermined period (dip method), and a method in which the rinse liquid is sprayed onto the surface of the support (spray method).

Since the resist composition according to the first aspect described above is used in the method for forming a resist pattern according to the present embodiment described above, it is presumed that a resist pattern having good resolution and good wet etching resistance can be obtained.

### EXAMPLES

Hereinafter, the present invention will be described in more detail based on Examples, but the present invention is not limited to these Examples.

### <Preparation of Resist Composition>

### Examples 1 to 21, Comparative Examples 1 to 3

Each of the components shown in Tables 1 to 3 was mixed and dissolved to prepare a resist composition of each Example.

TABLE 1

| | Component (A) | Component (B) | Component (C) | Component (D) | Component (Z) | Component (S) |
|---|---|---|---|---|---|---|
| Example 1 | (A)-1 | (B)-1 | (C)-1 | (D)-1 | (Z)-1 | (S)-1 |
| | [100] | [5.0] | [20] | [0.3] | [5.0] | [292] |
| Example 2 | (A)-1 | (B)-1 | (C)-1 | (D)-1 | (Z)-2 | (S)-1 |
| | [100] | [5.0] | [20] | [0.3] | [5.0] | [292] |
| Example 3 | (A)-1 | (B)-1 | (C)-1 | (D)-1 | (Z)-3 | (S)-1 |
| | [100] | [5.0] | [20] | [0.3] | [5.0] | [292] |
| Example 4 | (A)-1 | (B)-1 | (C)-1 | (D)-1 | (Z)-4 | (S)-1 |
| | [100] | [5.0] | [20] | [0.3] | [5.0] | [292] |
| Example 5 | (A)-1 | (B)-1 | (C)-1 | (D)-1 | (Z)-5 | (S)-1 |
| | [100] | [5.0] | [20] | [0.3] | [5.0] | [292] |
| Example 6 | (A)-1 | (B)-1 | (C)-1 | (D)-1 | (Z)-6 | (S)-1 |
| | [100] | [5.0] | [20] | [0.3] | [5.0] | [292] |
| Example 7 | (A)-1 | (B)-1 | (C)-1 | (D)-1 | (Z)-7 | (S)-1 |
| | [100] | [5.0] | [20] | [0.3] | [5.0] | [292] |
| Example 8 | (A)-1 | (B)-1 | (C)-1 | (D)-1 | (Z)-8 | (S)-1 |
| | [100] | [5.0] | [20] | [0.3] | [5.0] | [292] |
| Example 9 | (A)-1 | (B)-1 | (C)-1 | (D)-1 | (Z)-9 | (S)-1 |
| | [100] | [5.0] | [20] | [0.3] | [5.0] | [292] |
| Example 10 | (A)-1 | (B)-1 | (C)-1 | (D)-1 | (Z)-10 | (S)-1 |
| | [100] | [5.0] | [20] | [0.3] | [5.0] | [292] |

TABLE 2

| | Component (A) | Component (B) | | Component (C) | Component (D) | Component (Z) | Component (S) |
|---|---|---|---|---|---|---|---|
| Example 11 | (A)-1 | (B)-2 | — | (C)-1 | (D)-1 | (Z)-1 | (S)-1 |
| | [100] | [5.0] | | [20] | [0.3] | [5.0] | [292] |
| Example 12 | (A)-1 | (B)-2 | — | (C)-1 | (D)-1 | (Z)-2 | (S)-1 |
| | [100] | [5.0] | | [20] | [0.3] | [5.0] | [292] |
| Example 13 | (A)-1 | (B)-2 | — | (C)-1 | (D)-1 | (Z)-3 | (S)-1 |
| | [100] | [5.0] | | [20] | [0.3] | [5.0] | [292] |
| Example 14 | (A)-1 | (B)-1 | (B)-3 | (C)-1 | (D)-1 | (Z)-2 | (S)-1 |
| | [100] | [5.0] | [1.0] | [15] | [0.3] | [10.0] | [292] |
| Example 15 | (A)-1 | (B)-2 | (B)-3 | (C)-1 | (D)-1 | (Z)-2 | (S)-1 |
| | [100] | [5.0] | [1.0] | [15] | [0.3] | [10.0] | [292] |
| Example 16 | (A)-1 | (B)-2 | — | (C)-1 | (D)-1 | (Z)-2 | (S)-1 |
| | [100] | [5.0] | | [15] | [0.3] | [15.0] | [292] |
| Example 17 | (A)-1 | (B)-2 | — | (C)-1 | (D)-1 | (Z)-2 | (S)-1 |
| | [100] | [5.0] | | [15] | [0.3] | [3.0] | [292] |
| Example 18 | (A)-1 | (B)-2 | — | (C)-1 | (D)-1 | (Z)-2 | (S)-1 |
| | [100] | [5.0] | | [15] | [0.3] | [2.0] | [292] |
| Example 19 | (A)-1 | (B)-2 | — | (C)-1 | (D)-1 | (Z)-2 | (S)-1 |
| | [100] | [5.0] | | [15] | [0.3] | [1.0] | [292] |
| Example 20 | (A)-2 | (B)-1 | — | (C)-1 | (D)-1 | (Z)-2 | (S)-1 |
| | [100] | [5.0] | | [20] | [0.3] | [5.0] | [292] |
| Example 21 | (A)-1 | (B)-1 | — | (C)-1 | (D)-1 | (Z)-2 | (S)-1 |
| | [100] | [5.0] | | [20] | [0.3] | [20.0] | [292] |

TABLE 3

| | Component (A) | Component (B) | Component (C) | Component (D) | Component (Z) | Component (S) |
|---|---|---|---|---|---|---|
| Comparative | (A)-1 | (B)-1 | (C)-1 | (D)-1 | — | (S)-1 |
| Example 1 | [100] | [5.0] | [20] | [0.3] | | [292] |
| Comparative | (A)-1 | (B)-1 | (C)-1 | (D)-1 | (Z)-2 | (S)-1 |
| Example 2 | [100] | [5.0] | [20] | [0.3] | [50.0] | [292] |
| Comparative | (A)-1 | (B)-1 | (C)-11 | (D)-1 | (Z)-2 | (S)-1 |
| Example 3 | [100] | [5.0] | [20] | [0.3] | [5.0] | [292] |

In Tables 1 to 3, each abbreviation has the following meaning. The numerical values in the brackets are blending amounts (parts by mass).

(A)-1: The polymeric compound represented by Chemical Formula (A-1). This polymeric compound (A-1) was obtained by anionic polymerization using monomers from which constitutional units constituting the polymeric compound are derived, at a predetermined molar ratio. As a result of a GPC measurement to determine the weight average molecular weight (Mw) in terms of the standard polystyrene equivalent value, this polymeric compound (A-1) had a weight average molecular weight of 2,500 and a molecular weight dispersity (Mw/Mn) of 1.2. The copolymerization composition ratio (the ratio (molar ratio) among constitutional units in the structural formula) determined by ¹³C-NMR is l/m=90/10.

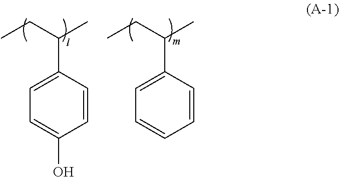

(A)-2: The polymeric compound (homopolymer) represented by Chemical Formula (A-2). This polymeric compound (A-2) was obtained by anionic polymerization using a monomer (hydroxystyrene) from which constitutional units constituting the polymeric compound are derived. As a result of a GPC measurement to determine the weight average molecular weight (Mw) in terms of the standard polystyrene equivalent value, this polymeric compound (A-2) had a weight average molecular weight of 2,500 and a molecular weight dispersity (Mw/Mn) of 1.2.

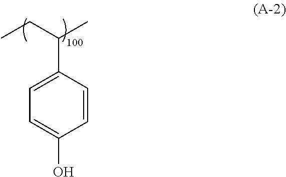

(B)-1 to (B)-3: Acid generators consisting of compounds each represented by Chemical Formulae (B-1) to (B-3).

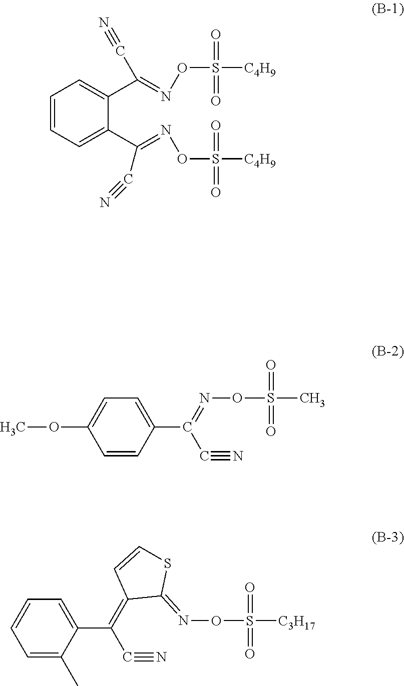

(C)-1: A crosslinking agent consisting of a compound represented by Chemical Formula (C-1).

(C)-11: A crosslinking agent consisting of a compound represented by Chemical Formula (C-11).

(D)-1: A nitrogen-containing organic compound consisting of a compound represented by Chemical Formula (D-1).

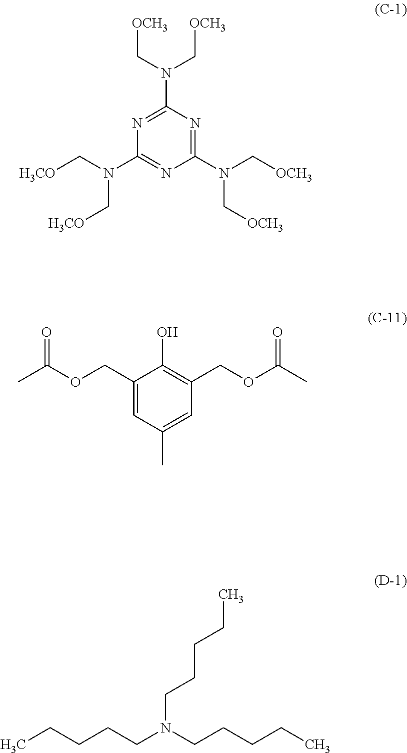

(Z)-1: Polypropylene glycol having a mass average molecular weight (Mw) of 400, represented by Chemical Formula (Z-1).

(Z)-2: Polypropylene glycol having a mass average molecular weight (Mw) of 1,000, represented by Chemical Formula (Z-1).

(Z)-3: Polypropylene glycol having a mass average molecular weight (Mw) of 3,000, represented by Chemical Formula (Z-1).

(Z)-4: Polypropylene glycol having a mass average molecular weight (Mw) of 4,000, represented by Chemical Formula (Z-1).

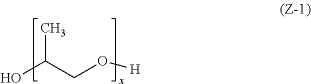

(Z)-5: Polyethylene glycol having a mass average molecular weight (Mw) of 1,000, represented by the following chemical formula (Z-2).

(Z)-6: Polyethylene glycol having a mass average molecular weight (Mw) of 4,000, represented by Chemical Formula (Z-2).

(Z)-7: Polyethylene glycol having a mass average molecular weight (Mw) of 8,000, represented by Chemical Formula (Z-2).

(Z)-8: Polyethylene glycol having a mass average molecular weight (Mw) of 20,000, represented by Chemical Formula (Z-2).

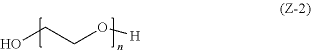

(Z)-9: Polytetrahydrofuran having a mass average molecular weight (Mw) of 1,000, represented by Chemical Formula (Z-3).

(Z)-10: Polytetrahydrofuran having a mass average molecular weight (Mw) of 2,000, represented by Chemical Formula (Z-3).

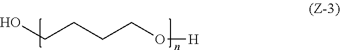

(S)-1: propylene glycol monomethyl ether acetate.

### <Method for Forming Resist Pattern>

### Step (i):

The resist composition of each Example was applied onto a silicon substrate which had been subjected to a hexamethyldisilazane (HMDS) treatment using a spinner, the coated wafer was subjected to a post-apply baking (PAB) treatment on a hot plate at 90° C. for 90 seconds so that the coated wafer was dried to form a resist film having a film thickness of 3 μm.

### Step (ii):

Next, the resist film was selectively irradiated with a high-pressure mercury lamp (365 nm) by an i-line stepper (reduction projection exposure apparatus: NSR-2205i14E (manufactured by Nikon Corporation; numerical aperture (NA)=0.57, σ=0.67)) through a mask pattern.

Thereafter, a post-exposure baking (PEB) treatment was performed on the resist film at 110° C. for 60 seconds.

Step (iii):

Subsequently, alkali development was performed under the conditions of 23° C. and 60 seconds using a 2.38% by mass tetramethylammonium hydroxide (TMAH) aqueous solution “NMD-3” (product name, manufactured by TOKYO OHKA KOGYO CO., LTD.) as a developing solution.

Then, a baking treatment (post-baking) was carried out at 100° C. for 60 seconds.

As a result, an isolated line pattern (hereinafter, referred to as an “IS pattern”) having a space width of 700 nm and a pitch of 3,500 nm was formed.

In Comparative Examples 2 and 3, the IS pattern was not resolved.

### [Evaluation of Sensitivity]

The optimum exposure amount Eop (mJ/cm²) for forming an IS pattern having a space width of 700 nm and a pitch of 3,500 nm was determined in <Resist pattern formation> described above. The results are shown in Tables 4 to 6 as “Eop (mJ/cm²)”.

### [Evaluation of Resolution]

The minimum size of the pattern that was resolved without being collapsed when forming an LS pattern by gradually increasing the exposure amount from the optimum exposure amount Eop for forming an IS pattern having a target size according to <Resist pattern formation> described above was determined using a scanning electron microscope S-9380 (manufactured by Hitachi High-Tech Corporation). The results are shown in Tables 4 to 6 as “Resolution (nm)”.

### <Wet Etching Resistance Evaluation>

Apart of the substrate on which the IS pattern had been formed according to the above-described method for forming a resist pattern was cut out and immersed in buffered hydrofluoric acid of 23% for 12 minutes.

The cross-sectional shape of the IS pattern after the immersion was observed with a scanning electron microscope (product name: S4500; manufactured by Hitachi, Ltd.), and the side etching (μm) (notching occurred due to etching at the interface between the resist film and the substrate interface) was evaluated. The results are shown in Tables 4 to 6 as “Side etching amount (μm)”.

TABLE 4

| | Eop | Resolution | Side etching amount |
|---|---|---|---|
| | (mJ/cm²) | (nm) | (μm) |
| Example 1 | 75 | 500 | 2.3 |
| Example 2 | 75 | 500 | 2.3 |
| Example 3 | 80 | 500 | 2.4 |
| Example 4 | 80 | 500 | 2.4 |
| Example 5 | 75 | 500 | 2.3 |
| Example 6 | 80 | 500 | 2.4 |
| Example 7 | 80 | 500 | 2.4 |
| Example 8 | 80 | 520 | 2.6 |
| Example 9 | 80 | 550 | 2.7 |
| Example 10 | 80 | 550 | 2.7 |

TABLE 5

| | Eop | Resolution | Side etching amount |
|---|---|---|---|
| | (mJ/cm²) | (nm) | (μm) |
| Example 11 | 75 | 500 | 2.3 |
| Example 12 | 75 | 500 | 2.3 |
| Example 13 | 80 | 500 | 2.4 |
| Example 14 | 70 | 550 | 1.7 |
| Example 15 | 70 | 550 | 1.7 |
| Example 16 | 85 | 590 | 1.3 |
| Example 17 | 70 | 490 | 2.8 |
| Example 18 | 70 | 480 | 3.2 |
| Example 19 | 70 | 480 | 3.7 |
| Example 20 | 85 | 510 | 2.4 |
| Example 21 | 90 | 700 | 1.1 |

TABLE 6

| | Eop | Resolution | Side etching amount |
|---|---|---|---|
| | (mJ/cm²) | (nm) | (μm) |
| Comparative | 70 | 480 | 4.1 |
| Example 1 | | | |
| Comparative | — | Not resolved | — |
| Example 2 | | | |
| Comparative | — | Not resolved | — |
| Example 3 | | | |

From the results shown in Tables 4 to 6, it has been confirmed that the resist patterns formed using the resist compositions of Examples 1 to 21 have good resolution and good wet etching resistance. In particular, it has been confirmed that good characteristics are obtained in the resist patterns formed using the resist compositions of Examples 1 to 20 from the viewpoint of achieving both resolution and wet etching resistance.

While preferred Examples according to the present invention have been described above; however, the present invention is not limited to these Examples. Additions, omissions, substitutions, and other modifications can be made without departing from the gist or scope of the present invention. Accordingly, the present invention is not to be considered as being limited by the foregoing description and is only limited by the scope of the appended claims.

What is claimed is:

1. A resist composition comprising:
a polymeric compound (A1) having a constitutional unit (a10) represented by General Formula (a10-1);
an acid generator (B);
at least one crosslinking agent (C) selected from the group consisting of a melamine-based crosslinking agent, a urea-based crosslinking agent, an alkylene urea-based crosslinking agent, a glycoluril-based crosslinking agent, and an epoxy-based crosslinking agent; and
a polyether compound (Z), wherein a content of the polyether compound (Z) is less than 50 parts by mass with respect to 100 parts by mass of the polymeric compound (A1), 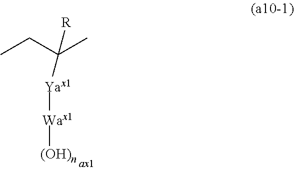
wherein R represents a hydrogen atom, an alkyl group having 1 to 5 carbon atoms, or a halogenated alkyl group having 1 to 5 carbon atoms, Ya^{x1} represents a single bond or a divalent linking group, Wa^{x1} represents an aromatic hydrocarbon group which may have a substituent, and nₐₓ₁ represents an integer of 1 or more.

2. The resist composition according to claim 1, wherein a content of the polyether compound (Z) is less than 20 parts by mass with respect to 100 parts by mass of the polymeric compound (A1).

3. The resist composition according to claim 1, wherein the polyether compound (Z) has a mass average molecular weight (Mw) of 200 to 25,000.

4. The resist composition according to claim 1, wherein the acid generator (B) includes an acid generator (B0) represented by General Formula (b0-1), 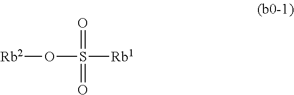
wherein Rb¹ represents an organic group, and Rb² represents a group represented by General Formula (b0-r-1) or General Formula (b0-r-2): 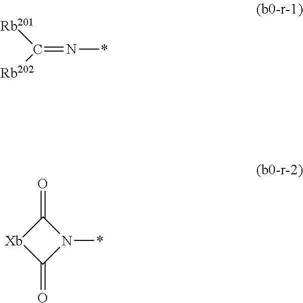
wherein in General Formula (b0-r-1), Rb²⁰¹ and Rb²⁰² each independently represents an organic group, and * represents a bonding site, and in General Formula (b0-r-2), Xb represents a group that forms a cyclic group having a cyclic imide structure, together with —(O═)C—N—C(═O)—, and * represents a bonding site.

5. A method for forming a resist pattern, comprising:
forming a resist film on a support using the resist composition according to claim 1;
exposing the resist film; and
developing the exposed resist film to form a resist pattern.
